(19) United States
(12) Patent Application Publication
(10) Pub. No.: US 2025/0300679 A1
(43) Pub. Date: Sep. 25, 2025

(54) MULTI-STAGE IMPEDANCE TUNING IN RADIO FREQUENCY TRANSMITTER

(71) Applicant: QUALCOMM Incorporated, San Diego, CA (US)

(72) Inventors: Hakan INANOGLU, Acton, MA (US); Erwin SPITS, Utrecht (NL); Leon METREAUD, Pepperell, MA (US); Frederic CARREZ, Boxborough, MA (US)

(21) Appl. No.: 18/611,139

(22) Filed: Mar. 20, 2024

(51) Int. Cl. H04B 1/00; H04B 1/04; H04B 17/13

(52) U.S. Cl. CPC H04B 1/0078; H04B 1/04; H04B 17/13; H04B 2001/0408

(57) ABSTRACT

Certain aspects of the present disclosure provide techniques for multi-stage impedance tuning for a radio frequency (RF) transmitter. An example apparatus includes RF circuitry comprising an amplifier, an impedance tuning circuit coupled to an output of the amplifier, and an antenna tuner coupled between an antenna feed and an output of the impedance tuning circuit. The apparatus further includes one or more memories and one or more processors coupled to the one or more memories. The one or more processors are configured to cause the apparatus to configure at least one parameter of the impedance tuning circuit or the amplifier based at least in part on at least one load characteristic at the antenna feed; and communicate one or more signals via the RF circuitry while the at least one parameter is configured based at least in part on the at least one load characteristic at the antenna feed.

### INTRODUCTION

### Field of the Disclosure

Aspects of the present disclosure relate to wireless communications, and more particularly, to impedance tuning of a radio frequency (RF) transmitter.

### Description of Related Art

Wireless communications systems are widely deployed to provide various telecommunication services such as telephony, video, data, messaging, broadcasts, etc. These wireless communications systems may employ multiple-access technologies capable of supporting communications with multiple users by sharing available wireless communications system resources with those users. Wireless communication devices may communicate RF signals via any of various suitable radio access technologies (RATs) including, but not limited to, 5G New Radio (NR), Evolved Universal Terrestrial Radio Access (E-UTRA), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., Institute of Electrical and Electronics Engineers (IEEE) 802.11 specifications), any future RAT, and/or the like.

In certain cases, a wireless communications device is equipped with a radio frequency (RF) transceiver (also referred to as an RF front-end) for communicating RF signals. In general, a baseband signal is modulated to convey information using a modulation technique, such as phase-shift keying (PSK) or any other suitable modulation technique. In a transmit mode, the RF transceiver is responsible for multiplexing the baseband signal with an RF carrier signal that is transmitted over the air (e.g., a wireless communication channel). Such an operation is called upconversion. In a receive mode, the RF transceiver converts a received RF signal to the baseband signal. Such an operation is called downconversion. The received baseband signal then can be demodulated into the information encoded at a transmitter. The RF transceiver may include a cascade of components in a transmit chain and a receive chain, respectively. The cascade of components may include, for example, one or more of attenuators, switches, couplers, filters, mixers, amplifiers, frequency synthesizers, oscillators, antenna tuners, duplexers, diplexers, detectors, etc.

### SUMMARY

Some aspects provide an apparatus configured for wireless communications. The apparatus includes radio frequency (RF) circuitry comprising one or more amplifiers, one or more impedance tuning circuits coupled to one or more outputs of the one or more amplifiers, and an antenna tuner coupled between an antenna feed and one or more outputs of the one or more impedance tuning circuits. The apparatus further includes one or more memories. The apparatus also includes one or more processors coupled to the one or more memories. The one or more processors are configured to cause the apparatus to configure at least one parameter of at least one of the one or more impedance tuning circuits or the one or more amplifiers based at least in part on at least one load characteristic at the antenna feed; and communicate one or more signals via the RF circuitry while the at least one parameter is configured based at least in part on the at least one load characteristic at the antenna feed.

Some aspects provide a method of wireless communications by an apparatus. The method includes configuring at least one parameter of at least one of one or more impedance tuning circuits or one or more amplifiers based at least in part on at least one load characteristic at an antenna feed, wherein the apparatus comprises radio frequency (RF) circuitry comprising the one or more amplifiers, the one or more impedance tuning circuits coupled to one or more outputs of the one or more amplifiers, and an antenna tuner coupled between the antenna feed and one or more outputs of the one or more impedance tuning circuits. The method further includes communicating one or more signals via the RF circuitry while the at least one parameter is configured based at least in part on at least one load characteristic at the antenna feed.

Some aspects provide a radio frequency transmitter. The radio frequency transmitter comprises: one or more amplifiers; one or more impedance tuning circuits coupled to one or more outputs of the one or more amplifiers; an antenna tuner coupled between an antenna feed and one or more outputs of the one or more impedance tuning circuits; one or more memories; and one or more processors coupled to the one or more memories, the one or more processors being configured to: configure a tuning index of at least one of the one or more impedance tuning circuits or the one or more amplifiers based at least in part on at least one load characteristic at the antenna feed; and communicate one or more signals while the tuning index is configured based at least in part on the at least one load characteristic at the antenna feed.

Other aspects provide: an apparatus operable, configured, or otherwise adapted to perform any one or more of the aforementioned methods and/or those described elsewhere herein; a non-transitory, computer-readable medium comprising instructions that, when executed by a processor of an apparatus, cause the apparatus to perform the aforementioned methods as well as those described elsewhere herein; a computer program product embodied on a computer-readable storage medium comprising code for performing the aforementioned methods as well as those described elsewhere herein; and/or an apparatus comprising means for performing the aforementioned methods as well as those described elsewhere herein. By way of example, an apparatus may comprise a processing system, a device with a processing system, or processing systems cooperating over one or more networks.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the drawings. It is to be noted, however, that the appended drawings illustrate only certain typical aspects of this disclosure and are therefore not to be considered limiting of its scope, for the description may admit to other equally effective aspects.

FIG. 1 illustrates an example wireless communications system.

FIG. 2 illustrates an example wireless communication device communicating with another device.

FIG. 3 illustrates an example radio frequency transmitter with multi-stage impedance tuning.

FIG. 4 illustrates an example mapping of error vector magnitudes and combinations of an antenna load and a tuning index of an impedance tuning circuit.

FIG. 5 illustrates an example mapping of power amplifier output powers and combinations of an antenna load and a tuning index.

FIG. 6 illustrates an example artificial intelligence (AI) architecture that may be used for AI-enhanced wireless communications.

FIG. 7 illustrates an example artificial neural network.

FIG. 8 illustrates an example architecture for training an ML model to determine a multi-stage tuning configuration.

FIG. 9 illustrates example operations for wireless communications by an apparatus.

FIG. 10 illustrates a communications device that may include various components configured to perform operations for the techniques disclosed herein.

To facilitate understanding, identical reference numerals have been used, where possible, to designate identical elements that are common to the figures. It is contemplated that elements disclosed in one aspect may be beneficially utilized in other aspects without specific recitation.

### DETAILED DESCRIPTION

Aspects of the present disclosure provide apparatus, methods, processing systems, and computer-readable mediums for multi-stage impedance tuning for a radio frequency (RF) transmitter.

In certain aspects, an RF transmitter may use a power amplifier (PA) to amplify a signal for transmission via an antenna. For example, the PA may convert a low-power RF signal into a higher power RF signal, and the output of the power amplifier may drive the antenna to emit RF energy. The performance (e.g., power output, efficiency, etc.) of the PA may be configured using certain resonant circuitry coupled to the output of the PA. In certain cases, the resonant circuitry may have an adjustable impedance, which may be adjusted to match an impedance of a load coupled to the PA as the output impedance of the PA varies over time, for example, due to changes in RF carrier frequency, output power, compression, gain, etc. In some cases, the impedance of the resonant circuitry may be adjusted under the assumption that the load impedance at the output of the PA remains fixed (e.g., 50 ohms). The load may be representative of certain RF circuitry and/or conditions including, for example, an antenna switch module, an antenna tuner, antenna(s), and any power reflections.

Technical problems for an RF transmitter include, for example, realizing effective performance of a PA in an RF transmitter. For certain wireless communications devices (e.g., portable devices such as cellular phones or smartphones), the antenna load impedance and load phase (e.g., a complex antenna impedance) may change depending on various factors, such as the RF environment (e.g., RF reflections, interference, and/or noise), the RF carrier frequency, the output power, etc. An antenna tuner may be coupled between the RF transmitter and an antenna, and the antenna tuner may be tuned to match the impedance of the RF transmitter to the complex antenna impedance, for example, to maximize the power delivery to the antenna. As an example, the antenna tuner may include an impedance matching network that is tuned to match the complex antenna impedance at an antenna feed, which may be or include output terminals and/or a transmission line that couple(s) an antenna to the RF transmitter. The complex impedance seen at the output of the PA may be a function of loss between the PA and the antenna and complex reflection coefficient at the antenna feed. A high voltage standing wave ratio (VSWR) at the antenna feed impacts the linearization of the PA, and thus, affects certain performance metrics including adjacent channel leakage ratio (ACLR), error vector magnitude (EVM), power output, etc. Accordingly, the complex impedance seen at the output of the PA may vary depending on, for example, an antenna tuner stage (e.g., the impedance of the matching network) of the antenna tuner and the RF environment (e.g., RF reflections, interference, and/or noise). Thus, the antenna impedance load and load phase seen at the antenna can impact the performance of the PA, for example, in terms of digital predistortion (DPD), power output, ACLR, EVM, and/or power output efficiency, especially when impedance matching at the PA is configured based on a fixed load rather than a varying load.

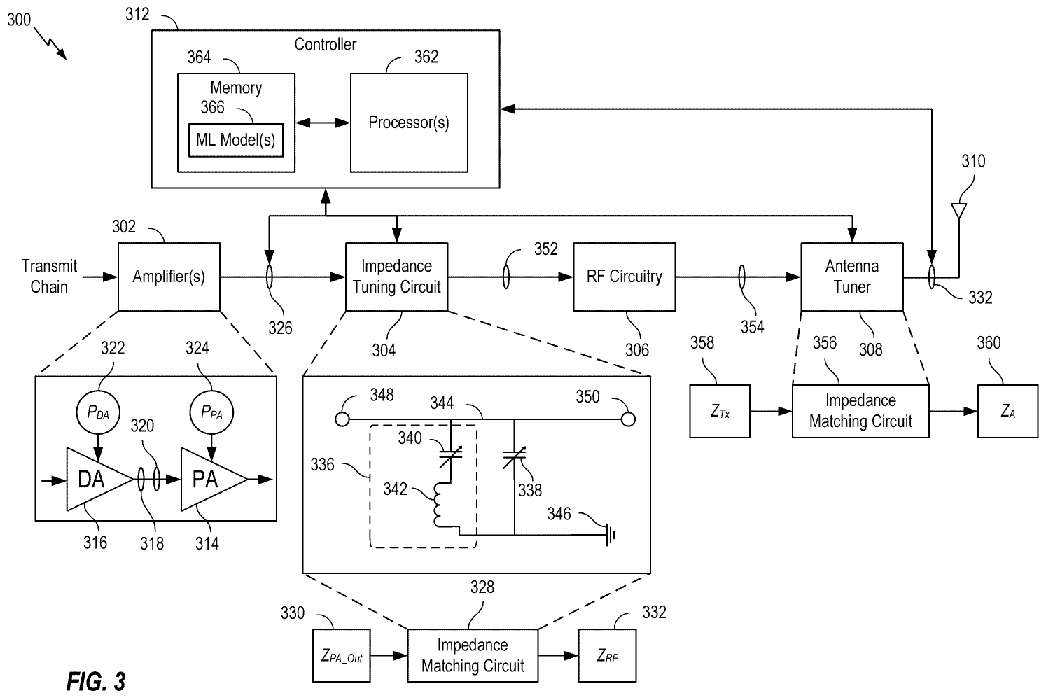

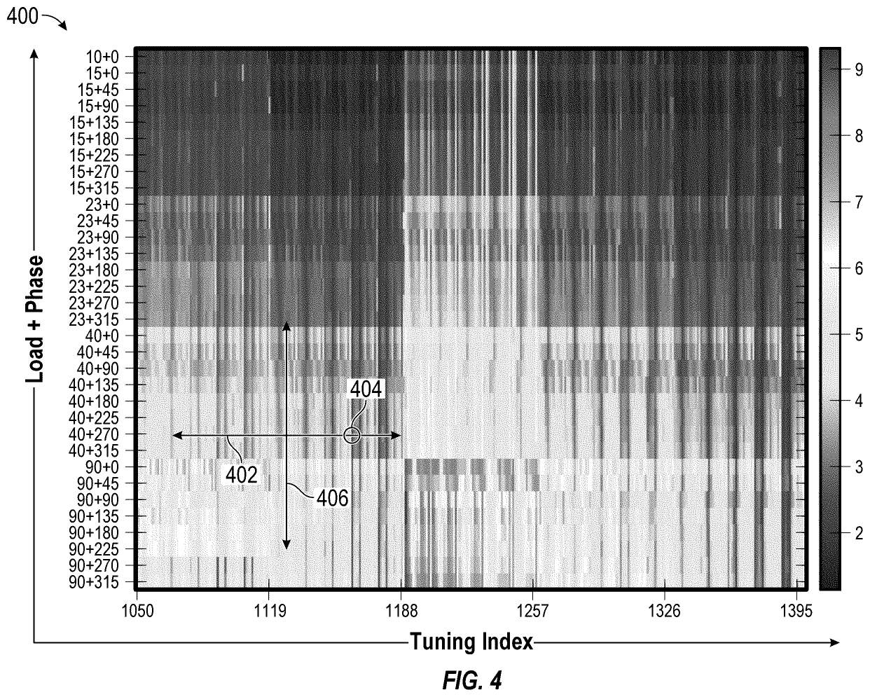

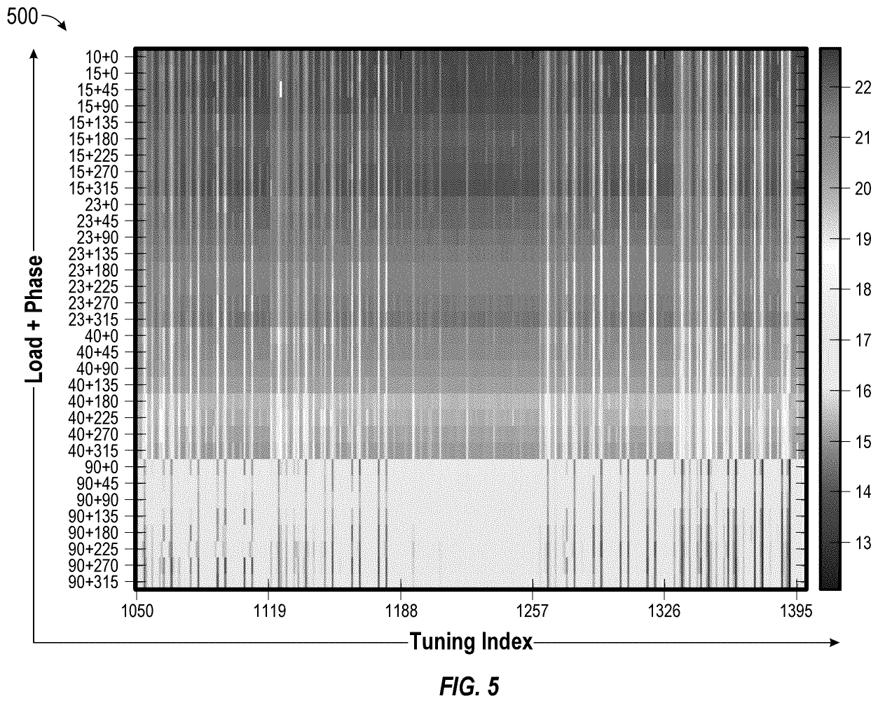

Aspects described herein overcome the aforementioned technical problem(s) by providing multi-stage impedance tuning for an RF transmitter. In certain aspects, an impedance tuning circuit may be arranged between an output of an amplifier (e.g., PA) and an antenna tuner in the RF transmitter, and the impedance tuning circuit along with the antenna tuner may be tuned based on the antenna impedance (e.g., a complex antenna impedance including an impedance load and load phase) as further described herein with respect to FIG. 3. In certain aspects, the tuning of the impedance tuning circuit may be characterized via a mapping (e.g., a heatmap and/or look-up table (LUT)) between a performance metric of the RF circuitry (e.g., ACLR, EVM, power output efficiency, etc.) and a combination of the antenna impedance and a tuning index (or tuning state) of the impedance tuning circuit, for example, as further described herein with respect to FIGS. 4 and 5. As an example, the tuning index may correspond to and/or represent a reactance of a reactive component (e.g., a variable capacitor) of the impedance tuning circuit and/or a biasing current or voltage applied to the PA. A controller may determine the tuning of the impedance tuning circuit that maps to a target performance metric and a current antenna impedance based on the mapping. In some cases, a machine learning (ML) model may be used to identify the tuning of the impedance tuning circuit given at least the current antenna impedance (and in some cases the target performance metric), as further described herein with respect to FIG. 3. For example, the ML model may effectively be trained to learn the mapping discussed above and find the tuning index of the impedance tuning circuit. Such multi-stage impedance tuning can effectively enable the output impedance of the PA to take into account the varying load of the antenna and/or RF circuitry coupled to the output of the PA, for example, due to the impedance matching applied at the antenna tuner and/or RF environment (e.g., reflections from surrounding objects and/or internal circuitry).

The techniques for multi-stage impedance tuning described herein may provide various beneficial effects and/or advantages. The techniques for multi-stage impedance tuning may enable improved performance of a PA in an RF transmitter, for example, in terms of linearization, ACLR, EVM, power output efficiency, etc. In some cases, the multi-stage impedance tuning may help restore PA linearization without online DPD (e.g., recalibrating and training the DPD weights associated with the PA), which can consume a non-trivial amount of time, processing resources, and/or power. The improved PA performance may be attributable to the impedance tuning at the PA output taking into account the varying load of the antenna and/or RF circuitry coupled to the output of the PA. In certain aspects, the mapping discussed herein may allow the RF transmitter to satisfy one or more target performance metrics, such as linearization, ACLR, EVM, power output efficiency, etc. In certain aspects, the ML-based multi-stage tuning described herein may enable improved PA performance, for example, due to an ML model being trained to identify settings for certain impedance tuning circuit parameters that can achieve one or more PA performance metrics.

### Example Wireless Communications System

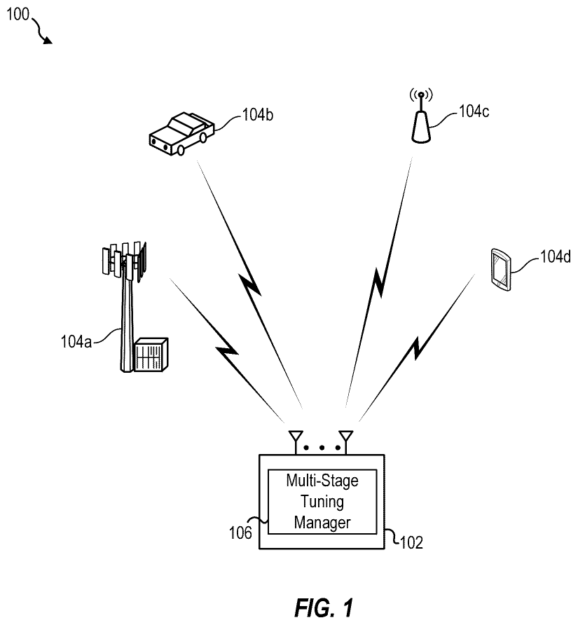

FIG. 1 illustrates an example wireless communications system 100 in which aspects of the present disclosure may be performed. For example, the wireless communications system 100 may include a wireless wide area network (WWAN) and/or a wireless local area network (WLAN). A WWAN may include a New Radio (NR) system (e.g., a Fifth Generation (5G) NR network), an Evolved Universal Terrestrial Radio Access (E-UTRA) system (e.g., a Fourth Generation (4G) network), a Universal Mobile Telecommunications System (UMTS) (e.g., a Second Generation (2G) or Third Generation (3G) network), a code division multiple access (CDMA) system (e.g., a 2G/3G network), any future WWAN system, or any combination thereof. A WLAN may include a wireless network configured for communications according to an Institute of Electrical and Electronics Engineers (IEEE) standard such as one or more of the 802.11 standards, etc. In some cases, the wireless communications system 100 may include a device-to-device (D2D) communications network or a short-range communications system, such as Bluetooth communications and/or near field communications (NFC).

As illustrated in FIG. 1, the wireless communications system 100 may include a first wireless device 102 communicating with any of various second wireless devices 104a-d (hereinafter “the second wireless device 104”) via any of various radio access technologies (RATs), where a wireless device may refer to a wireless communications device. The RATs may include, for example, WWAN communications (e.g., E-UTRA and/or 5G NR), WLAN communications (e.g., IEEE 802.11), vehicle-to-everything (V2X) communications, non-terrestrial network (NTN) communications, short-range communications (e.g., Bluetooth and/or NFC), etc.

The first wireless device 102 may include any of various wireless communications devices including a user equipment (UE), a base station, a wireless station, an access point, customer-premises equipment (CPE), etc. In certain aspects, the first wireless device 102 includes a multi-stage tuning manager 106 that configures a tuning index of an impedance tuning circuit arranged between an output of an amplifier and an antenna tuner in an RF transmitter, in accordance with aspects of the present disclosure.

The second wireless device 104 may include, for example, a base station 104a, a vehicle 104b, an access point (AP) 104c, and/or a UE 104d. Further, the wireless communications systems 100 may include terrestrial aspects, such as ground-based network entities (e.g., the base station 104a and/or access point 104e), and/or non-terrestrial aspects, such as a spaceborne platform and/or an aerial platform, which may include network entities on-board (e.g., one or more base stations) capable of communicating with other network elements (e.g., terrestrial base stations) and/or user equipment.

The base station 104a may generally include: a NodeB, enhanced NodeB (eNB), next generation enhanced NodeB (ng-eNB), next generation NodeB (gNB or gNodeB), access point, base transceiver station, radio base station, radio transceiver, transceiver function, transmission reception point, and/or others. The base station 104a may provide communications coverage for a respective geographic coverage area, which may sometimes be referred to as a cell, and which may overlap in some cases (e.g., a small cell may have a coverage area that overlaps the coverage area of a macro cell). A base station may, for example, provide communications coverage for a macro cell (covering relatively large geographic area), a pico cell (covering relatively smaller geographic area, such as a sports stadium), a femto cell (relatively smaller geographic area (e.g., a home)), and/or other types of cells.

The first wireless device 102 and/or the UE 104d may generally include: a cellular phone, smart phone, session initiation protocol (SIP) phone, laptop, personal digital assistant (PDA), satellite radio, global positioning system, multimedia device, video device, digital audio player, camera, game console, tablet, smart device, wearable device, vehicle, electric meter, gas pump, large or small kitchen appliance, healthcare device, implant, sensor/actuator, display, internet of things (IoT) devices, always on (AON) devices, edge processing devices, or other similar devices. A UE may also be referred to more generally as a mobile device, a wireless device, a wireless communications device, a wireless station (STA), a mobile station, a subscriber station, a mobile subscriber station, a mobile unit, a subscriber unit, a wireless unit, a remote unit, a remote device, an access terminal, a mobile terminal, a wireless terminal, a remote terminal, a handset, and other terms.

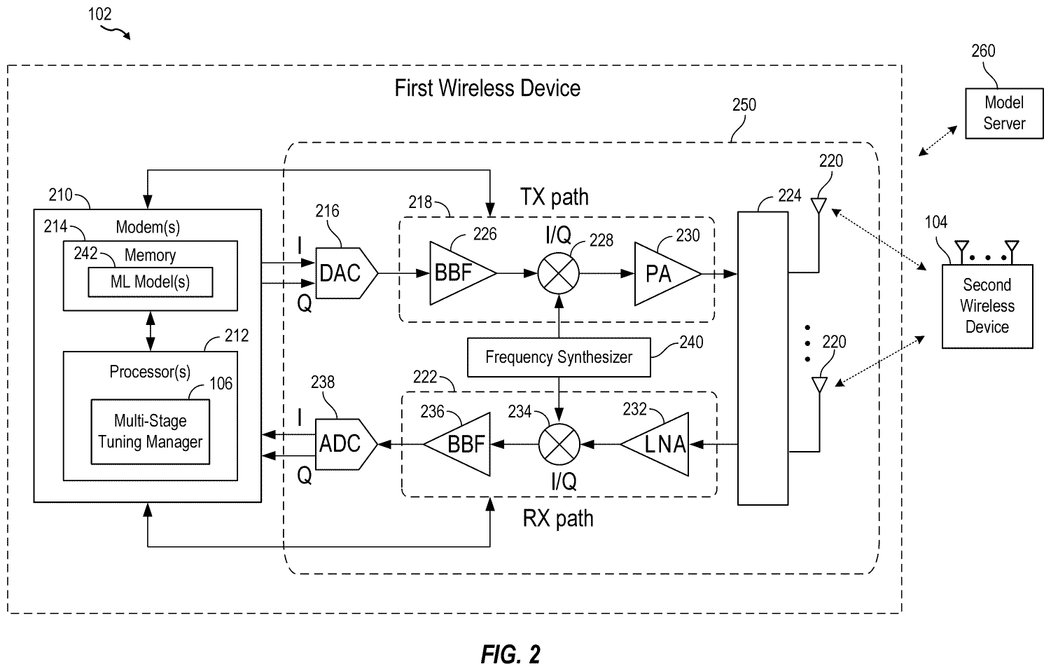

FIG. 2 illustrates example components of the first wireless device 102, which may be used to communicate with any of the second wireless devices 104.

The first wireless device 102 may be, or may include, a chip, system on chip (SoC), system in package (SiP), chipset, package, device that includes one or more modems 210 (hereinafter “the modem 210”). In some cases, the modem 210 may include, for example, any of a WWAN modem (e.g., a modem configured to communicate via E-UTRA 5G NR, and/or any future WWAN communications standards), a WLAN modem (e.g., a modem configured to communicate via IEEE 802.11 standards), a Bluetooth modem, a NTN modem, etc. In certain aspects, the first wireless device 102 also includes one or more RF transceivers (hereinafter “the RF transceiver 250”). In some cases, the RF transceiver 250 may be referred to as an RF front end (RFFE). In some aspects, the modem 210 further includes one or more processors, processing blocks or processing elements (hereinafter “the processor 212”) and one or more memory blocks or elements (hereinafter “the memory 214”). In some cases, the processor 212 may implement and/or include the multi-stage tuning manager 106 of FIG. 1.

In certain aspects, the processor 212 may process any of certain protocol stack layers associated with a radio access technology (RAT). For example, the processor 212 may process any of an application layer, packet layer, WLAN protocol stack layers (e.g., a link or a medium access control (MAC) layer), and/or WWAN protocol stack layers (e.g., a radio resource control (RRC) layer, a packet data convergence protocol (PDCP) layer, a radio link control (RLC) layer, and a MAC layer).

The modem 210 may generally be configured to implement a physical (PHY) layer. For example, the modem 210 may be configured to modulate packets and to output the modulated packets to the RF transceiver 250 for transmission over a wireless medium. The modem 210 is similarly configured to obtain modulated packets received by the RF transceiver 250 and to demodulate the packets to provide demodulated packets. In addition to a modulator and a demodulator, the modem 210 may further include digital signal processing (DSP) circuitry, automatic gain control (AGC), a coder, a decoder, a multiplexer, and/or a demultiplexer (not shown).

As an example, while in a transmission mode, the modem 210 may obtain data from a data source, such as an application processor. The data may be provided to a coder, which encodes the data to provide encoded bits. The encoded bits may be mapped to points in a modulation constellation (e.g., using a selected modulation and coding scheme) to provide modulated symbols. The modulated symbols may be mapped, for example, to spatial stream(s) or space-time streams. The modulated symbols may be multiplexed, transformed via an inverse fast Fourier transform (IFFT) block, and subsequently provided to DSP circuitry for transmit windowing and filtering. The digital signals may be provided to a digital-to-analog converter (DAC) 216. In certain aspects involving beamforming, the modulated symbols in the respective spatial streams may be precoded via a steering matrix prior to provision to the IFFT block.

The modem 210 may be coupled to the RF transceiver 250 by a transmit (TX) path 218 (also known as a transmit chain) for transmitting signals via one or more antennas 220 (hereinafter “the antennas 220”) and a receive (RX) path 222 (also known as a receive chain) for receiving signals via the antenna 220. When the TX path 218 and the RX path 222 share the antennas 220, the paths may be coupled to the antennas 220 via an interface 224, which may include any of various suitable RF devices, such as an antenna tuner, a switch, a duplexer, a diplexer, a multiplexer, and the like. As an example, the modem 210 may output digital in-phase (I) and/or quadrature (Q) baseband signals representative of the respective symbols to the DAC 216. In some examples, all or most of the elements illustrated as being included in the RF transceiver 250 are implemented in a single chip, die, or package, such as an RFFE integrated circuit. For example, in some configurations all of the elements of the RF transceiver except the antennas 220 are implemented on a single chip. In some other configurations, the interface 224 or a portion thereof is also omitted from the single chip.

Receiving I or Q baseband analog signals from the DAC 216, the TX path 218 may include a baseband filter (BBF) 226, a mixer 228 (which may include one or several mixers), and a power amplifier (PA) 230. The BBF 226 filters the baseband signals received from the DAC 216, and the mixer 227 mixes the filtered baseband signals with a transmit local oscillator (LO) signal to convert the baseband signal to a different frequency (e.g., upconvert from baseband to a radio frequency). In some aspects, the frequency conversion process produces the sum and difference frequencies between the LO frequency and the frequencies of the baseband signal. The sum and difference frequencies are referred to as the beat frequencies. Some beat frequencies are in the RF range, such that the signals output by the mixer 228 are typically RF signals, which may be amplified by the PA 230 before transmission by the antennas 220. The antennas 220 may emit RF signals, which may be received at the second wireless device 104. While one mixer 228 is illustrated, several mixers may be used to upconvert the filtered baseband signals to one or more intermediate frequencies and to thereafter upconvert the intermediate frequency signals to a frequency for transmission.

The RX path 222 may include a low noise amplifier (LNA) 232, a mixer 234 (which may include one or several mixers), and a baseband filter (BBF) 236. RF signals received via the antennas 220 (e.g., from the second wireless device 104) may be amplified by the LNA 232, and the mixer 234 mixes the amplified RF signals with a receive local oscillator (LO) signal to convert the RF signal to a baseband frequency (e.g., downconvert). The baseband signals output by the mixer 234 may be filtered by the BBF 236 before being converted by an analog-to-digital converter (ADC) 238 to digital I or Q signals for digital signal processing. The modem 210 may receive the digital I or Q signals and further process the digital signals, for example, demodulating the digital signals into information.

Certain transceivers may employ frequency synthesizers with a voltage-controlled oscillator (VCO) to generate a stable, tunable LO frequency with a particular tuning range. Thus, the transmit LO frequency may be produced by a frequency synthesizer 240, which may be buffered or amplified by an amplifier (not shown) before being mixed with the baseband signals in the mixer 228. Similarly, the receive LO frequency may be produced by the frequency synthesizer 240, which may be buffered or amplified by an amplifier (not shown) before being mixed with the RF signals in the mixer 234. Separate frequency synthesizers may be used for the TX path 218 and the RX path 222.

While in a reception mode, the modem 210 may obtain digitally converted signals via the ADC 238 and RX path 222. As an example, in the modem 210, digital signals may be provided to the DSP circuitry, which is configured to acquire a received signal, for example, by detecting the presence of the signal and estimating the initial timing and frequency offsets. The DSP circuitry is further configured to digitally condition the digital signals, for example, using channel (narrowband) filtering, analog impairment conditioning (such as correcting for I/Q imbalance), and applying digital gain to ultimately obtain a narrowband signal. The output of the DSP circuitry may be fed to the AGC, which is configured to use information extracted from the digital signals, for example, in one or more received training fields, to determine an appropriate gain. The output of the DSP circuitry also may be coupled with the demodulator, which is configured to extract modulated symbols from the signal and, for example, compute the logarithm likelihood ratios (LLRs) for each bit position of each subcarrier in each spatial stream. The demodulator may be coupled with the decoder, which may be configured to process the LLRs to provide decoded bits. The decoded bits from all of the spatial streams may be fed to the demultiplexer for demultiplexing. The demultiplexed bits may be descrambled and provided to a medium access control layer (e.g., the processor 212) for processing, evaluation, or interpretation.

The modem 210 and/or processor 212 may control the transmission of signals via the TX path 218 and/or reception of signals via the RX path 222. In some aspects, the modem 210 and/or processor 212 may be configured to perform various operations, such as those associated with any of the methods described herein. The modem 210 and/or processor 212 may include a microcontroller, a microprocessor, an application processor, a baseband processor, a MAC processor, an artificial intelligence (AI) processor, a digital signal processor (DSP), an application specific integrated circuit (ASIC), a field programmable gate array (FPGA) or other programmable logic device (PLD), discrete gate or transistor logic, discrete hardware components, or any combination thereof. The memory 214 may store data and program codes (e.g., processor-readable instructions) for performing wireless communications as described herein. In some cases, the memory 214 may be external to the modem 210 and/or processor 212 and/or incorporated therein (as illustrated).

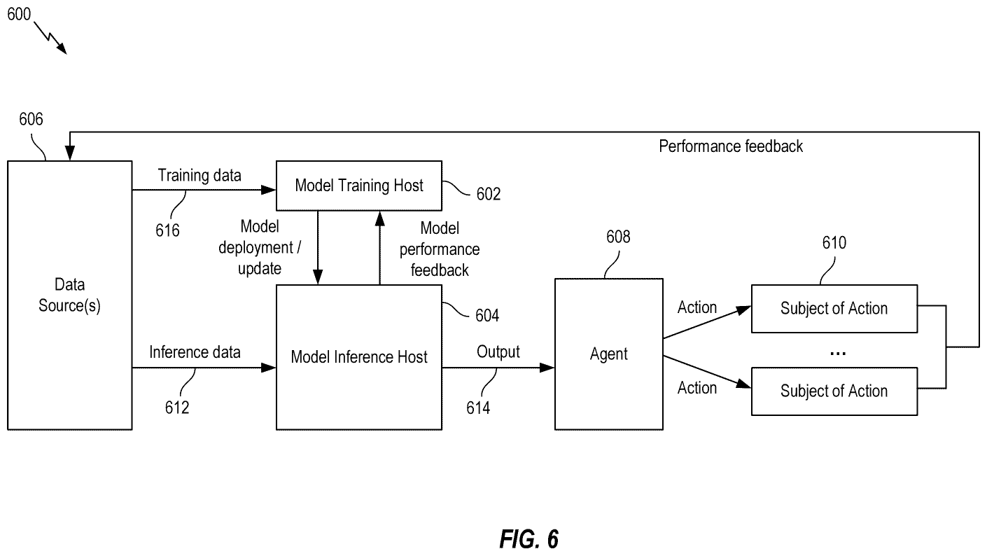

In certain aspects, one or more ML models 242 may be stored in the memory 214 and accessible to the processor 212. In certain cases, different ML models 242 with different characteristics may be stored in the memory 214, and a particular ML model 242 may be selected based on its characteristics and/or application as well as characteristics and/or conditions of the first wireless device 102 (e.g., a power state, a mobility state, a battery reserve, a temperature, etc.). For example, the ML models 242 may have different inference data and output pairings (e.g., different types of inference data produce different types of output), different levels of accuracies (e.g., 80%, 90%, or 95% accurate) associated with the predictions (e.g., output 614 of FIG. 6), different latencies (e.g., processing times of less than 10 milliseconds (ms), 100 ms, or 1 second) associated with producing the predictions, different ML model sizes (e.g., file sizes), different coefficients or weights, etc.

The processor 212 may use the ML model 242 to produce output data (e.g., the output 614 of FIG. 6) based on input data (e.g., the inference data 612 of FIG. 6), for example, as described herein with respect to the inference host 604 of FIG. 6. The ML model 242 may be used to perform any of various AI-enhanced tasks, such as those described herein. As an example, the ML model 242 may determine one or more tuning parameters to configure an impedance tuning circuit coupled to the output of the PA 230, as further described herein with respect to FIG. 3. Note that other input data and/or output data may be used in addition to or instead of the examples described herein.

In certain aspects, a model server 260 may perform any of various ML model lifecycle management (LCM) tasks for the first wireless device 102 and/or the second wireless device 104. The model server 260 may operate as a model training host (for example, as discussed with respect to FIG. 6) and update the ML model 242 using training data. In some cases, the model server 260 may operate as a data source (for example, as discussed with respect to FIG. 6) to collect and host training data, inference data, and/or performance feedback associated with the ML model 242. In certain aspects, the model server 260 may host various types and/or versions of the ML models 242 for the first wireless device 102 and/or the second wireless device 104 to download.

In some cases, the model server 260 may monitor and evaluate the performance of the ML model 242 to trigger one or more LCM tasks. For example, the model server 260 may determine whether to activate or deactivate the use of a particular ML model at the first wireless device 102 and/or the second wireless device 104, and the model server 260 may provide such an instruction to the respective first wireless device 102 and/or the second wireless device 104. In some cases, the model server 260 may determine whether to switch to a different ML model 242 being used at the first wireless device 102 and/or the second wireless device 104, and the model server 260 may provide such an instruction to the respective first wireless device 102 and/or the second wireless device 104. In yet further examples, the model server 260 may also act as a central server for decentralized machine learning tasks, such as federated learning, as further discussed herein.

FIG. 2 shows an example transceiver design. It will be appreciated that other transceiver designs or architectures may be applied in connection with aspects of the present disclosure. For example, while examples discussed herein utilize I and Q signals (e.g., quadrature modulation), those of skill in the art will understand that components of the transceiver may be configured to utilize any other suitable modulation, such as polar modulation. As another example, circuit blocks may be arranged differently from the configuration shown in FIG. 2, and/or other circuit blocks not shown in FIG. 2 may be implemented in addition to or instead of the blocks depicted.

Certain aspects described herein may be implemented, at least in part, using some form of artificial intelligence (AI), e.g., the process of using a machine learning (ML) model to infer or predict output data based on input data. An example ML model may include a mathematical representation of one or more relationships among various objects to provide an output representing one or more predictions or inferences. Once an ML model has been trained, the ML model may be deployed to process data that may be similar to, or associated with, all or part of the training data and provide an output representing one or more predictions or inferences based on the input data.

ML is often characterized in terms of types of learning that generate specific types of learned models that perform specific types of tasks. For example, different types of machine learning include supervised learning, unsupervised learning, semi-supervised learning, and reinforcement learning.

Supervised learning algorithms generally model relationships and dependencies between input features (e.g., a feature vector) and one or more target outputs. Supervised learning uses labeled training data, which are data including one or more inputs and a desired output. Supervised learning may be used to train models to perform tasks like classification, where the goal is to predict discrete values, or regression, where the goal is to predict continuous values. Some example supervised learning algorithms include nearest neighbor, naive Bayes, decision trees, linear regression, support vector machines (SVMs), and artificial neural networks (ANNs).

Unsupervised learning algorithms work on unlabeled input data and train models that take an input and transform it into an output to solve a practical problem. Examples of unsupervised learning tasks are clustering, where the output of the model may be a cluster identification, dimensionality reduction, where the output of the model is an output feature vector that has fewer features than the input feature vector, and outlier detection, where the output of the model is a value indicating how the input is different from a typical example in the dataset. An example unsupervised learning algorithm is k-Means.

Semi-supervised learning algorithms work on datasets containing both labeled and unlabeled examples, where often the quantity of unlabeled examples is much higher than the number of labeled examples. However, the goal of a semi-supervised learning is that of supervised learning. Often, a semi-supervised model includes a model trained to produce pseudo-labels for unlabeled data that is then combined with the labeled data to train a second classifier that leverages the higher quantity of overall training data to improve task performance.

Reinforcement Learning algorithms use observations gathered by an agent from an interaction with an environment to take actions that may maximize a reward or minimize a risk. Reinforcement learning is a continuous and iterative process in which the agent learns from its experiences with the environment until it explores, for example, a full range of possible states. An example type of reinforcement learning algorithm is an adversarial network. Reinforcement learning may be particularly beneficial when used to improve or attempt to optimize a behavior of a model deployed in a dynamically changing environment, such as a wireless communication network.

ML models may be deployed in one or more devices (e.g., network entities such as base station(s) and/or user equipment(s)) to support various wired and/or wireless communication aspects of a communication system. For example, an ML model may be trained to identify patterns and relationships in data corresponding to a network, a device, an air interface, or the like. An ML model may improve operations relating to one or more aspects, such as transceiver circuitry controls, frequency synchronization, timing synchronization, channel state estimation, channel equalization, channel state feedback, modulation, demodulation, device positioning, transceiver tuning, beamforming, signal coding/decoding, network routing, load balancing, and energy conservation (to name just a few) associated with communications devices, services, and/or networks. AI-enhanced transceiver circuitry controls may include, for example, filter tuning, transmit power controls, gain controls (including automatic gain controls), phase controls, power management, and the like.

Aspects described herein may describe the performance of certain tasks and the technical solution of various technical problems by application of a specific type of ML model, such as an ANN. It should be understood, however, that other type(s) of AI models may be used in addition to or instead of an ANN. An ML model may be an example of an AI model, and any suitable AI model may be used in addition to or instead of any of the ML models described herein. Hence, unless expressly recited, subject matter regarding an ML model is not necessarily intended to be limited to just an ANN solution or machine learning. Further, it should be understood that, unless otherwise specifically stated, terms such “AI model,” “ML model,” “AI/ML model,” “trained ML model,” and the like are intended to be interchangeable.

### Example Multi-Stage Impedance Tuning in an RF Transmitter

Aspects of the present disclosure provide techniques for multi-stage impedance tuning in an RF transmitter that enable improved performance of a PA in an RF transmitter, for example, in terms of linearization, ACLR, EVM, power output efficiency, etc.

FIG. 3 illustrates an example RF transmitter 300 with multi-stage impedance tuning. The RF transmitter 300 may be an example of a TX path, such as the TX path 218 of FIG. 2 or aspects thereof. The RF transmitter 300 may include one or more amplifiers 302 (hereinafter “the amplifier 302”), one or more impedance tuning circuits 304 (hereinafter “the impedance tuning circuit 304”), an antenna tuner 308, an antenna 310, and a controller 312. In some cases, the RF transmitter 300 may also include RF circuitry 306 coupled between the impedance tuning circuit 304 and the antenna tuner 308.

The amplifier 302 may be or include a power amplifier (PA) 314 that converts a lower power RF signal to a higher power RF signal. In some cases, the amplifier 302 may be or include a driver amplifier (DA) 316 coupled to the PA 314. For example, the DA 316 and PA 314 may form a cascade of amplifiers where an output 318 of the DA 316 is coupled to an input 320 of the PA 314. The DA 316 and the PA 314 may be used to provide multiple stages of amplification to the RF signal. In certain aspects, each of the DA 316 and the PA 314 may have a power rail that supplies power to the respective amplifier. A supply voltage and/or supply current may feed into the power rail of the amplifier. In this example, one or more power supplies 322, 324 may feed into one or more power rails of the respective amplifier 314, 316. As further discussed herein, the current and/or voltage level of the power supplies 322, 324 may be used as tuning parameter(s) for the amplifier 302. The power supplies 332, 324 may correspond to a supply current, a supply voltage, a reference current, a quiescent current, a reference voltage, a biasing voltage, and/or a biasing current fed to one or more transistors (not shown) of the DA 316 and/or PA 314. In certain aspects, the power supplies 322, 324 may serve as biasing current(s) and/or biasing voltage(s) applied to one or more transistors of the DA 316 and/or PA 314. For example, a biasing current and/or voltage may be fed to a collector of one or more transistor(s) of the DA 316 and/or PA 314 to tune the collector impedance(s) of the transistor(s) of the DA 316 and/or PA 314.

The impedance tuning circuit 304 is arranged between an output 326 of the amplifier 302 and the antenna tuner 308. In this example, the impedance tuning circuit 304 is coupled to the output 326 (e.g., one or more outputs) of the amplifier 302. In certain aspects, any of the elements of the tuning circuit 304 may be wholly or partially arranged at or on the same chip, die, or module of the amplifier 302. In certain aspects, any of the elements of the tuning circuit 304 may be partially or wholly integrated with the amplifier 302. In certain aspects, the tuning circuit 304 may be arranged at or in the same package or module as the amplifier 302 (e.g., either partially at or on a die of the PA 314 or separate from the die of the PA 314). In certain aspects, the tuning circuit 304 may be wholly separate from a chip, die, or module in or on which the amplifier 302 is disposed.

In certain aspects, the impedance tuning circuit 304 may tune an output impedance of the amplifier 302 based on a load impedance of subsequent RF circuitry in the transmit chain. The impedance tuning circuit 304 may be configured to adjust its impedance to balance the impedances of the amplifier 302 and the RF circuitry 306, for example. In certain aspects, the impedance tuning circuit 304 may operate as a first impedance matching circuit 328 configured to increase power transfer to the antenna 310 and/or reduce power being reflected to the amplifier 302. In some cases, the first impedance matching circuit 328 may be configured to effectively match an amplifier output impedance 330 (Z_{PA_Out}) to an RF circuit impedance 332 (Z_{RF}) of the RF circuitry 306. The impedance of the first impedance matching circuit 328 may depend on the output power of the amplifier 302, the tuning stage of the antenna tuner 308, any power loss across the RF circuitry 306 and/or antenna tuner 308, and/or complex reflection coefficient at an antenna feed 332, each of which may vary due to the transmitted signal power, carrier frequency, and/or RF environment (e.g., surrounding objects that cause RF reflections).

The impedance tuning circuit 304 may be or include one or more resonant circuits formed via one or more reactive components including, for example, one or more capacitors and/or one or more inductors. In this example, the impedance tuning circuit 304 includes a first resonant circuit 336 and/or a bypass capacitor 338 (e.g., a decoupling capacitor). The first resonant circuit 336 is formed via a first capacitor 340 coupled in series with a first inductor 342. The first resonant circuit 336 may be or include a notch filter, for example, tuned or configured to suppress certain harmonic distortions, as further discussed below. The first capacitor 340 may include a variable capacitor including, for example, an array of parallel capacitors in a capacitor bank and/or a varactor. The first resonant circuit 336 may be coupled between a signal path 344 and a reference potential node 346. The signal path 344 may be formed between an input node 348 and an output node 350 of the impedance tuning circuit 304. The bypass capacitor 338 may be coupled between the signal path 344 and the reference potential node 346. The bypass capacitor 338 may include a variable capacitor, such as an array of parallel capacitors in a capacitor bank and/or a varactor. As further discussed herein, the tunable capacitance of the variable capacitor(s) in the impedance tuning circuit 304 may be used as tuning parameter(s) for the impedance tuning circuit 304.

In certain aspects, the impedance tuning circuit 304 may be formed using certain filters that suppress noise and/or distortion of the RF transmitter 300, such as certain harmonic distortions. For example, the impedance tuning circuit 304 may be or include a harmonic trap tuned to suppress a second harmonic (e.g., 2 fo) and/or a third harmonic (e.g., 3 fo) of an RF carrier frequency. In this example, the first resonant circuit 336 may be configured to suppress a second harmonic of a particular RF carrier frequency. Note that the impedance tuning circuit 304 may include other filter(s) and/or resonant circuit(s) in addition to or instead of the first resonant circuit 336, such as low pass filter(s), notch filter(s), harmonic trap(s), bandpass filter(s), etc.

The RF circuitry 306 may be or include an antenna switching module that selectively couples the output 326 of the amplifier 302 to one or more antennas, such as the antenna 310. In some cases, the RF circuitry 306 may be used to selectively couple the amplifier to an antenna among multiple antennas, for example, multiple low-band antennas, multiple mid-band antennas, and multiple high-band antennas. Accordingly, the RF circuitry 306 may include a set of switches coupled to multiple antennas (not shown). In certain aspects, the RF circuitry 306 may have an impedance including a resistance and reactance (e.g., capacitance) that can affect the load impedance seen at the output of the amplifier 302.

The antenna tuner 308 is coupled between the amplifier 302 and the antenna 310. In certain aspects, the antenna tuner 308 is coupled between the antenna feed 332 and one or more outputs 352 of the impedance tuning circuit 304. In some cases, the RF circuitry 306 may be arranged between the amplifier 302 and the antenna tuner 308. For example, the antenna tuner 308 may be coupled to an output 354 of the RF circuitry 306.

The antenna tuner 308 comprises a second impedance matching circuit 356 configured to adjust its impedance to balance the impedances of the antenna 310 and transmit chain circuitry coupled to the antenna tuner 308. As an example, the second impedance matching circuit 356 may be or include a variable capacitor (not shown) including an array of parallel capacitors in a capacitor bank and/or a varactor. In certain aspects, the second impedance matching circuit 356 may be configured to increase power transfer to the antenna 310 and/or reduce power being reflected between the antenna 310 and the transmit chain circuitry. In some cases, the second impedance matching circuit 356 may be configured to effectively match a transmit chain impedance 358 (Z_{Tx}) to an antenna impedance 360 (Z_{A}) of the antenna 310 coupled to the antenna tuner 308. The transmit chain impedance 358 is the impedance of the transmit chain circuitry (e.g., the cascade of transmit chain circuitry including the amplifier 302, impedance tuning circuit 304, and the RF circuitry 306) coupled to the antenna tuner 308. The impedance of the second impedance matching circuit 356 may depend on the transmit chain impedance 358 and the antenna impedance 360, each of which may vary due to the transmit signal power and/or RF carrier frequency.

The controller 312 controls the multi-stage impedance tuning at the impedance tuning circuit 304 and/or the antenna tuner 308. In certain aspects, the controller 312 may include one or more processors 362 (hereinafter “the processor 362”) coupled to one or more memories 364 (hereinafter “the memory 364”). The processor 362 may be an example of the processor 212, and the memory 364 may be an example of the memory 214 of FIG. 2.

The controller 312 may obtain feedback at the antenna feed 332 and/or the output 326 of the amplifier 302, and the controller 312 may configure the impedance at the first impedance matching circuit 328 and/or the second impedance matching circuit 356 based on the feedback. The feedback may be or include an indication of an impedance load and/or load phase at the antenna feed 332 (e.g., the antenna impedance 360). In certain aspects, the feedback may be or include an indication of one or more performance metrics associated with the RF transmitter 300 (or any component thereof).

The controller 312 may configure the second impedance matching circuit 356 to match the impedance load and/or load phase observed at the antenna feed 332. The controller 312 may configure the impedance tuning circuit 304 in accordance with a relationship or mapping among one or more performance metrics of the RF transmitter 300, the antenna impedance 360 (Z_{A}), and/or a tuning index of the impedance tuning circuit 304. The performance metric(s) may include one or more of an operating temperature of the RF transmitter 300 (or any component thereof, such as the amplifier 302), an output frequency of the RF transmitter 300 (e.g., as characterized by a power spectral distribution associated with an output signal at the output 302 and/or the antenna feed 332), a voltage standing wave ratio (VSWR) of the RF transmitter 300, an error vector magnitude (EVM) of the RF transmitter 300, an adjacent channel leakage ratio (ACLR) of the RF transmitter 300, a peak-to-average power ratio (PAPR) of the RF transmitter 300, an output power level of the RF transmitter 300, a power-added efficiency (PAE) of the amplifier 302. The controller 312 may have access to a mapping of one or more performance metrics (e.g., EVM, ACLR, power efficiency, etc.) of the RF transmitter 300 to a combination of the antenna load (e.g., impedance load and phase) at the antenna feed 332 and a tuning index for the impedance tuning circuit 304, for example, as described herein with respect to FIGS. 4 and 5.

In certain aspects, the controller 312 may monitor the performance metric(s) associated with the RF transmitter 300, and the controller 312 may adjust the impedance at the first impedance matching circuit 328 and/or the second impedance matching circuit 356 in response to a change in the performance metric. In certain aspects, the controller 312 may monitor the performance metric(s) in order to generate the mapping of one or more performance metrics (e.g., EVM, ACLR, power efficiency, etc.) of the RF transmitter 300 to a combination of the antenna load (e.g., impedance load and phase) at the antenna feed 332 and a tuning index for the impedance tuning circuit 304. As an example, the controller 312 may monitor certain performance metric(s) via a feedback path between a transmit chain and receive chain, for example, a feedback path used for DPD calibration.

In some cases, the controller 312 may search for a tuning index in the mapping that corresponds to the current antenna impedance (e.g., impedance load and load phase) and a target performance metric (e.g., a low ACLR, a high PAE, a low PAPR, and/or a low EVM). The tuning index may correspond to one or more tuning parameters of at least one of the amplifier 302 or the impedance tuning circuit 304. For example, the tuning parameters may include a reference, quiescent, or biasing current of the power supplies 322, 324; a reactance of at least one reactive component of the impedance tuning circuit 304 (e.g., a capacitance value for the variable capacitors); quiescent and/or biasing current(s) and/or voltage(s) applied to transistor(s) of the PA 314 and/or DA 316; and/or a frequency variation associated with the impedance tuning circuit 304.

In certain aspects, the tuning parameters (e.g., the biasing currents and/or capacitances) may be characterized for each complex impedance seen at the output 326 of the amplifier 302. The impedance seen at the output 326 of the amplifier may be monitored, and the tuning parameters may be adjusted in response to the monitored impedance to deliver a target performance metric, which may include a combination of output power, ACLR, EVM, and/or power efficiency.

In certain aspects, the controller 312 may identify the tuning index for the impedance tuning circuit 304 using one or more ML models 366 (hereinafter “the ML model 366”), which may be stored in the memory 364. The ML model 366 may be an example of the ML model 242. The controller 312 may provide, to the ML model 366, input data comprising an antenna impedance, for example, as observed at the antenna feed 332. In certain aspects, the input data may include the current state of the tuning index and/or the antenna impedance. In certain aspects, the input data may include the antenna impedance and a target performance metric of the RF transmitter, and the ML model may identify the tuning index depending on the antenna impedance and the target performance metric. The output data may include the tuning index that is predicted to achieve certain performance metric(s) at the current state of the antenna impedance. The controller 312 may obtain, from the ML model 366, output data comprising the tuning index for the impedance tuning circuit. As an example, the ML model 366 may be trained to identify the tuning index based on the mapping discussed above. In general, the ML model 366 may effectively have knowledge of the performance of the RF transmitter under various antenna loads and tuning indexes, for example, in the form of the mapping discussed above. The controller 312 may use the ML model 366 to predict a particular tuning index that can achieve a target performance metric given a current state of the antenna impedance as observed at the antenna feed 332, for example, in the form of feedback to the controller 312.

FIG. 4 illustrates an example mapping 400 of EVMs and combinations of an antenna impedance and a tuning index of an impedance tuning circuit of an RF transmitter as described herein with respect to FIG. 3. The mapping 400 is shown as a heatmap of values for the EVM of the RF transmitter, where the y-axis represents different impedance loads and load phases, and the x-axis represents different tuning indexes of the impedance tuning circuit (e.g., the impedance tuning circuit 304 of FIG. 3). Each of the tuning indexes may correspond to a different combination of tuning parameters used to configure the impedance tuning circuit 304 and/or the amplifier 302, such as the power supplies 322, 324 and/or the capacitance values for the variable capacitors (e.g., the first capacitor 340 and the bypass capacitor 338). Suppose the current antenna impedance is observed at a load and load phase along the horizontal line 402, the controller 312 may search for (or use an ML model to identify) a tuning index that achieves the lowest EVM for that respective antenna impedance, for example, at location 404. Moreover, location 404 may allow for a relatively low EVM across a broad range of antenna impedances. Accordingly, the mapping 400 may be used to identify a tuning index that achieves a target performance metric across a range of antenna impedances. As the antenna impedance varies over time, for example, along the vertical line 406, the controller 312 may repeat the search for a tuning index that achieves the lowest EVM for the current antenna impedance. In some cases, the mapping 400 may be represented as a look-up table (or data structure) of combinations of EVMs, antenna impedances, and tuning indexes. In certain cases, an ML model (e.g., the ML model 366) may be trained to identify the tuning index in the mapping 400 given the current antenna impedance and/or a target EVM.

In certain aspects, the ML model may be trained to learn the mapping 400 or aspects thereof, and the ML model may identify a tuning index given the current antenna impedance and/or a target EVM based on knowledge (e.g., weights) representative of the mapping 400. In other words, the mapping 400 may be an example of the behavior of an RF transmitter that an ML model can be trained to learn in the form of relationships among various combinations of antenna impedances, tuning indexes, and one or more performance metrics.

FIG. 5 illustrates an example mapping 500 of PA output powers and combinations of an antenna load and a tuning index. The mapping 500 may be used to identify a tuning index for an impedance tuning circuit as described herein with respect FIG. 4. In certain cases, the controller 312 may search for (or use an ML model to identify) a tuning index that maximizes the output power of the PA based on the current antenna impedance. In some cases, the controller 312 may search for (or use an ML model to identify) a tuning index that achieves a particular output power of the PA based on the current antenna impedance.

In certain aspects, the controller 312 may search for a tuning index that achieves or is predicted to achieve multiple target performance metrics (e.g., EVM and output power) given a current state of the antenna impedance. For example, the controller 312 may use the mappings 400, 500 to identify a tuning index that reduces the EVM and increases the output power given a current antenna impedance.

Note the mappings illustrated in FIGS. 4 and 5 are examples of the mappings for certain performance metrics. Other mappings may be used in addition to or instead of those illustrated, such as mappings for ACLR, PAE, PAPR, linearization, etc.

### Example Artificial Intelligence for Wireless Communications

FIG. 6 is a diagram illustrating an example AI architecture 600 that may be used for AI-enhanced wireless communications. As illustrated, the architecture 600 includes multiple logical entities, such as a model training host 602, a model inference host 604, data source(s) 606, and an agent 608. The AI architecture may be used in any of various use cases for wireless communications, such as the multi-stage impedance tuning described herein.

The model inference host 604, in the architecture 600, is configured to run an ML model based on inference data 612 provided by data source(s) 606. The inference data 612 may be or include an antenna impedance (e.g., an impedance load and/or load phase) and/or a target performance metric. In some cases, the antenna impedance may be or include multiple impedances, for example, measured in a time window. In certain cases, the antenna impedance may be or include a peak value in the time window, a minimum (lowest) value in the time window, an average value in the time window, a median value in the time window, etc. The model inference host 604 may produce an output 614 (e.g., a prediction or inference, such as a discrete or continuous value) based on the inference data 612, that is then provided as input to the agent 608.

In certain aspects, the agent 608 may be or include a processor, modem, or controller of an RF transmitter. For example, the agent 608 may be the controller 312 of FIG. 3. Additionally, the type of agent 608 may also depend on the type of tasks performed by the model inference host 604, the type of inference data 612 provided to model inference host 604, and/or the type of output 614 produced by model inference host 604.

After the agent 608 receives output 614 from the model inference host 604, agent 608 may determine whether to act based on the output. For example, if agent 608 is a modem and the output from model inference host 604 identifies a tuning parameter (e.g., a tuning index) for the impedance tuning circuit 304 and/or the amplifier 302, the agent 608 may determine whether to configure the impedance tuning circuit based on the output 614. If the agent 608 determines to act based on the output 614, agent 608 may indicate the action to at least one subject of the action 610, for example, in the form of a control signal that is configured to tune the impedance tuning circuit.

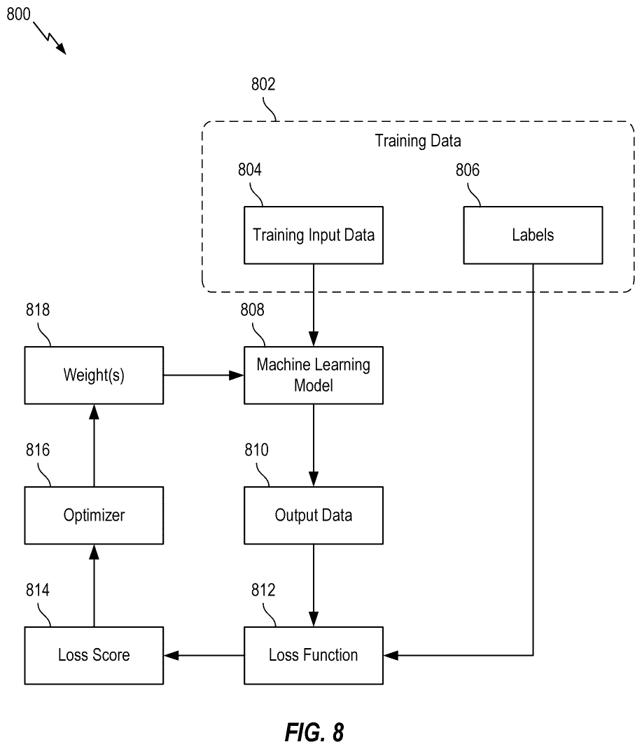

The data sources 606 may be configured for collecting data that is used as training data 616 for training an ML model, or as inference data 612 for feeding an ML model inference operation. The training data 616 may be or include antenna impedances with corresponding expected performance metrics and/or tuning indexes as further described herein with respect to FIG. 8. In particular, the data sources 606 may collect data from any of various entities, devices, or components (e.g., an RF transmitter), which may include the subject of action 610, and provide the collected data to a model training host 602 for ML model training. For example, a modem may collect performance feedback (e.g., one or more performance metrics including VSWR, EVM, ACLR, PAPR, PAE, etc.) associated with the multi-stage impedance tuning and provide such feedback to the data sources 606, where the performance feedback may be used by the model training host 602 for monitoring and/or evaluating the ML model performance, such as whether the output 614, provided to agent 608, is accurate. In some examples, if the output 614 provided to agent 608 is inaccurate (or the accuracy is below an accuracy threshold), the model training host 602 may determine to modify or retrain the ML model used by model inference host 604, such as via an ML model deployment/update.

In certain aspects, the model training host 602 may be deployed at or with the same or a different entity than that in which the model inference host 604 is deployed. For example, in order to offload model training processing, which can impact the performance of the model inference host 604, the model training host 602 may be deployed at a model server as described herein with respect to FIG. 2. Further, in some cases, training and/or inference may be distributed amongst devices in a decentralized or federated fashion.

### Example Artificial Intelligence Model

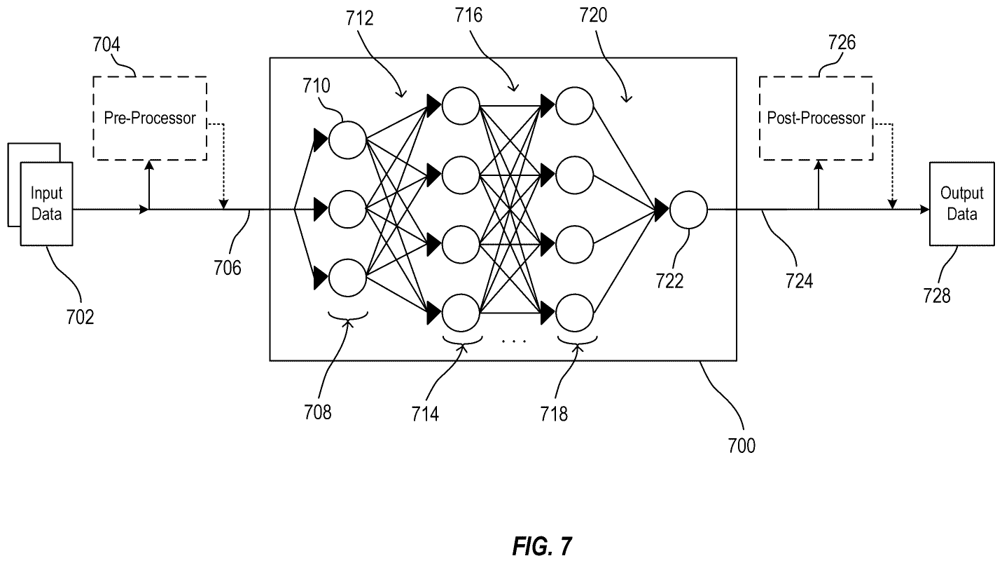

FIG. 7 is an illustrative block diagram of an example artificial neural network (ANN) 700.

ANN 700 may receive input data 706 which may include one or more bits of data 702, pre-processed data output from pre-processor 704 (optional), or some combination thereof. Here, data 702 may include training data, verification data, application-related data, or the like, e.g., depending on the stage of development and/or deployment of ANN 700. Pre-processor 704 may be included within ANN 700 in some other implementations. Pre-processor 704 may, for example, process all or a portion of data 702 which may result in some of data 702 being changed, replaced, deleted, etc. In some implementations, pre-processor 704 may add additional data to data 702.

ANN 700 includes at least one first layer 708 of artificial neurons 710 (e.g., perceptrons) to process input data 706 and provide resulting first layer output data via edges 712 to at least a portion of at least one second layer 714. Second layer 714 processes data received via edges 712 and provides second layer output data via edges 716 to at least a portion of at least one third layer 718. Third layer 718 processes data received via edges 716 and provides third layer output data via edges 720 to at least a portion of a final layer 722 including one or more neurons to provide output data 724. All or part of output data 724 may be further processed in some manner by (optional) post-processor 726. Thus, in certain examples, ANN 700 may provide output data 728 that is based on output data 724, post-processed data output from post-processor 726, or some combination thereof. Post-processor 726 may be included within ANN 700 in some other implementations. Post-processor 726 may, for example, process all or a portion of output data 724 which may result in output data 728 being different, at least in part, to output data 724, e.g., as result of data being changed, replaced, deleted, etc. In some implementations, post-processor 726 may be configured to add additional data to output data 724. In this example, second layer 714 and third layer 718 represent intermediate or hidden layers that may be arranged in a hierarchical or other like structure. Although not explicitly shown, there may be one or more further intermediate layers between the second layer 714 and the third layer 718.

The structure and training of artificial neurons 710 in the various layers may be tailored to specific requirements of an application. Within a given layer of an ANN, some or all of the neurons may be configured to process information provided to the layer and output corresponding transformed information from the layer. For example, transformed information from a layer may represent a weighted sum of the input information associated with or otherwise based on a non-linear activation function or other activation function used to “activate” artificial neurons of a next layer. Artificial neurons in such a layer may be activated by or be responsive to weights and biases that may be adjusted during a training process. Weights of the various artificial neurons may act as parameters to control a strength of connections between layers or artificial neurons, while biases may act as parameters to control a direction of connections between the layers or artificial neurons. An activation function may select or determine whether an artificial neuron transmits its output to the next layer or not in response to its received data. Different activation functions may be used to model different types of non-linear relationships. By introducing non-linearity into an ML model, an activation function allows the ML model to “learn” complex patterns and relationships in the input data (e.g., 606 in FIG. 6). Some non-exhaustive example activation functions include a linear function, binary step function, sigmoid, hyperbolic tangent (tanh), a rectified linear unit (ReLU) and variants, exponential linear unit (ELU), Swish, Softmax, and others.

Design tools (such as computer applications, programs, etc.) may be used to select appropriate structures for ANN 700 and a number of layers and a number of artificial neurons in each layer, as well as selecting activation functions, a loss function, training processes, etc. Once an initial model has been designed, training of the model may be conducted using training data. Training data may include one or more datasets within which ANN 700 may detect, determine, identify or ascertain patterns. Training data may represent various types of information, including written, visual, audio, environmental context, operational properties, etc. During training, parameters of artificial neurons 710 may be changed, such as to minimize or otherwise reduce a loss function or a cost function. A training process may be repeated multiple times to fine-tune ANN 700 with each iteration.

Various ANN model structures are available for consideration. For example, in a feedforward ANN structure each artificial neuron 710 in a layer receives information from the previous layer and likewise produces information for the next layer. In a convolutional ANN structure, some layers may be organized into filters that extract features from data (e.g., training data and/or input data). In a recurrent ANN structure, some layers may have connections that allow for processing of data across time, such as for processing information having a temporal structure, such as time series data forecasting.

In an autoencoder ANN structure, compact representations of data may be processed and the model trained to predict or potentially reconstruct original data from a reduced set of features. An autoencoder ANN structure may be useful for tasks related to dimensionality reduction and data compression.

A generative adversarial ANN structure may include a generator ANN and a discriminator ANN that are trained to compete with each other. Generative-adversarial networks (GANs) are ANN structures that may be useful for tasks relating to generating synthetic data or improving the performance of other models.

A transformer ANN structure makes use of attention mechanisms that may enable the model to process input sequences in a parallel and efficient manner. An attention mechanism allows the model to focus on different parts of the input sequence at different times. Attention mechanisms may be implemented using a series of layers known as attention layers to compute, calculate, determine or select weighted sums of input features based on a similarity between different elements of the input sequence. A transformer ANN structure may include a series of feedforward ANN layers that may learn non-linear relationships between the input and output sequences. The output of a transformer ANN structure may be obtained by applying a linear transformation to the output of a final attention layer. A transformer ANN structure may be of particular use for tasks that involve sequence modeling, or other like processing.

Another example type of ANN structure, is a model with one or more invertible layers. Models of this type may be inverted or “unwrapped” to reveal the input data that was used to generate the output of a layer.

Other example types of ANN model structures include fully connected neural networks (FCNNs) and long short-term memory (LSTM) networks.

ANN 700 or other ML models may be implemented in various types of processing circuits along with memory and applicable instructions therein, for example, as described herein with respect to FIGS. 2, 3, and 6. For example, general-purpose hardware circuits, such as, such as one or more central processing units (CPUs) and one or more graphics processing units (GPUs) may be employed to implement a model. One or more ML accelerators, such as tensor processing units (TPUs), embedded neural processing units (eNPUs), or other special-purpose processors, and/or field-programmable gate arrays (FPGAs), application-specific integrated circuits (ASICs), or the like also may be employed. Various programming tools are available for developing ANN models.

### Aspects of Artificial Intelligence Model Training

There are a variety of model training techniques and processes that may be used prior to, or at some point following, deployment of an ML model, such as ANN 700 of FIG. 7.

As part of a model development process, information in the form of applicable training data may be gathered or otherwise created for use in training an ML model accordingly. For example, training data may be gathered or otherwise created regarding information associated with received/transmitted signal strengths, interference, and resource usage data, as well as any other relevant data that might be useful for training a model to address one or more problems or issues in a communication system. In certain instances, all or part of the training data may originate in one or more user equipments (UEs), one or more network entities, or one or more other devices in a wireless communication system. In some cases, all or part of the training data may be aggregated from multiple sources (e.g., one or more UEs, one or more network entities, the Internet, etc.). For example, wireless network architectures, such as self-organizing networks (SONs) or mobile drive test (MDT) networks, may be adapted to support collection of data for ML model applications. In another example, training data may be generated or collected online, offline, or both online and offline by a UE, network entity, or other device(s), and all or part of such training data may be transferred or shared (in real or near-real time), such as through store and forward functions or the like. Offline training may refer to creating and using a static training dataset, e.g., in a batched manner, whereas online training may refer to a real-time or near-real-time collection and use of training data. For example, an ML model at a network device (e.g., a UE) may be trained and/or fine-tuned using online or offline training. For offline training, data collection and training can occur in an offline manner at the network side (e.g., at a base station or other network entity) or at the UE side. For online training, the training of a UE-side ML model may be performed locally at the UE or by a server device (e.g., a server hosted by a UE vendor) in a real-time or near-real-time manner based on data provided to the server device from the UE.

In certain instances, all or part of the training data may be shared within a wireless communication system, or even shared (or obtained from) outside of the wireless communication system.

Once an ML model has been trained with training data, its performance may be evaluated. In some scenarios, evaluation/verification tests may use a validation dataset, which may include data not in the training data, to compare the model's performance to baseline or other benchmark information. If model performance is deemed unsatisfactory, it may be beneficial to fine-tune the model, e.g., by changing its architecture, re-training it on the data, or using different optimization techniques, etc. Once a model's performance is deemed satisfactory, the model may be deployed accordingly. In certain instances, a model may be updated in some manner, e.g., all or part of the model may be changed or replaced, or undergo further training, just to name a few examples.

As part of a training process for an ANN, such as ANN 700 of FIG. 7, parameters affecting the functioning of the artificial neurons and layers may be adjusted. For example, backpropagation techniques may be used to train the ANN by iteratively adjusting weights and/or biases of certain artificial neurons associated with errors between a predicted output of the model and a desired output that may be known or otherwise deemed acceptable. Backpropagation may include a forward pass, a loss function, a backward pass, and a parameter update that may be performed in training iteration. The process may be repeated for a certain number of iterations for each set of training data until the weights of the artificial neurons/layers are adequately tuned.

Backpropagation techniques associated with a loss function may measure how well a model is able to predict a desired output for a given input. An optimization algorithm may be used during a training process to adjust weights and/or biases to reduce or minimize the loss function which should improve the performance of the model. There are a variety of optimization algorithms that may be used along with backpropagation techniques or other training techniques. Some initial examples include a gradient descent based optimization algorithm and a stochastic gradient descent based optimization algorithm. A stochastic gradient descent (or ascent) technique may be used to adjust weights/biases in order to minimize or otherwise reduce a loss function. A mini-batch gradient descent technique, which is a variant of gradient descent, may involve updating weights/biases using a small batch of training data rather than the entire dataset. A momentum technique may accelerate an optimization process by adding a momentum term to update or otherwise affect certain weights/biases.

An adaptive learning rate technique may adjust a learning rate of an optimization algorithm associated with one or more characteristics of the training data. A batch normalization technique may be used to normalize inputs to a model in order to stabilize a training process and potentially improve the performance of the model.

A “dropout” technique may be used to randomly drop out some of the artificial neurons from a model during a training process, e.g., in order to reduce overfitting and potentially improve the generalization of the model.

An “early stopping” technique may be used to stop an on-going training process early, such as when a performance of the model using a validation dataset starts to degrade.

Another example technique includes data augmentation to generate additional training data by applying transformations to all or part of the training information.

A transfer learning technique may be used which involves using a pre-trained model as a starting point for training a new model, which may be useful when training data is limited or when there are multiple tasks that are related to each other.

A multi-task learning technique may be used which involves training a model to perform multiple tasks simultaneously to potentially improve the performance of the model on one or more of the tasks. Hyperparameters or the like may be input and applied during a training process in certain instances.

Another example technique that may be useful with regard to an ML model is some form of a “pruning” technique. A pruning technique, which may be performed during a training process or after a model has been trained, involves the removal of unnecessary (e.g., because they have no impact on the output) or less necessary (e.g., because they have negligible impact on the output), or possibly redundant features from a model. In certain instances, a pruning technique may reduce the complexity of a model or improve efficiency of a model without undermining the intended performance of the model.

Pruning techniques may be particularly useful in the context of wireless communication, where the available resources (such as power and bandwidth) may be limited. Some example pruning techniques include a weight pruning technique, a neuron pruning technique, a layer pruning technique, a structural pruning technique, and a dynamic pruning technique. Pruning techniques may, for example, reduce the amount of data corresponding to a model that may need to be transmitted or stored.

Weight pruning techniques may involve removing some of the weights from a model. Neuron pruning techniques may involve removing some neurons from a model. Layer pruning techniques may involve removing some layers from a model. Structural pruning techniques may involve removing some connections between neurons in a model. Dynamic pruning techniques may involve adapting a pruning strategy of a model associated with one or more characteristics of the data or the environment. For example, in certain wireless communication devices, a dynamic pruning technique may more aggressively prune a model for use in a low-power or low-bandwidth environment, and less aggressively prune the model for use in a high-power or high-bandwidth environment. In certain aspects, pruning techniques also may be applied to training data, e.g., to remove outliers, etc. In some implementations, pre-processing techniques directed to all or part of a training dataset may improve model performance or promote faster convergence of a model. For example, training data may be pre-processed to change or remove unnecessary data, extraneous data, incorrect data, or otherwise identifiable data. Such pre-processed training data may, for example, lead to a reduction in potential overfitting, or otherwise improve the performance of the trained model.

One or more of the example training techniques presented above may be employed as part of a training process. As above, some example training processes that may be used to train an ML model include supervised learning, unsupervised learning, semi-supervised learning, and reinforcement learning technique.

Decentralized, distributed, or shared learning, such as federated learning, may enable training on data distributed across multiple devices or organizations, without the need to centralize data or the training. Federated learning may be particularly useful in scenarios where data is sensitive or subject to privacy constraints, or where it is impractical, inefficient, or expensive to centralize data. In the context of wireless communication, for example, federated learning may be used to improve performance by allowing an ML model to be trained on data collected from a wide range of devices and environments. For example, an ML model may be trained on data collected from a large number of wireless devices in a network, such as distributed wireless communication nodes, smartphones, or internet-of-things (IoT) devices, to improve the network's performance and efficiency. With federated learning, a user equipment (UE) or other device may receive a copy of all or part of a model and perform local training on such copy of all or part of the model using locally available training data. Such a device may provide update information (e.g., trainable parameter gradients) regarding the locally trained model to one or more other devices (such as a network entity or a server) where the updates from other-like devices (such as other UEs) may be aggregated and used to provide an update to a shared model or the like. A federated learning process may be repeated iteratively until all or part of a model obtains a satisfactory level of performance. Federated learning may enable devices to protect the privacy and security of local data, while supporting collaboration regarding training and updating of all or part of a shared model.

### Aspects of Training a Machine Learning Model for Multi-Stage Tuning

FIG. 8 illustrates an example architecture 800 for training an ML model to determine a multi-stage tuning configuration of an RF transmitter. The architecture 800 may be implemented by a model training host (e.g., the model training host 602 of FIG. 6). In some cases, the model training host may be or include the modem 210, the processor 212, and/or the controller 312. In certain aspects, the model training host may be or include the model server 260, which may collect training data from one or more wireless communications devices (e.g., the first wireless device 102).

The model training host obtains training data 802 including training input data 804 and/or corresponding labels 806 for the training input data 804. The training input data 804 may include samples of antenna impedances (e.g., representative of current antenna impedances that are fed back to the controller 312). In some cases, a sample antenna impedance may be or include multiple impedances, for example, measured in (or simulated for) a time window. The sample antenna impedance may include a time series of antenna impedances. In certain cases, the sample antenna impedance may be or include a peak (highest) value in the time window, a minimum (lowest) value in the time window, an average value in the time window, a median value in the time window, etc. In certain cases, the training input data 804 may include target performance metric(s) for the tuning index to achieve. In some cases, the training input data 804 may include one or more performance mappings (e.g., the mapping(s) 400, 500) that are used to search for a tuning index given an antenna impedance. The training input data 804 may be simulated (e.g., computer generated) and/or collected from performance characterizations (e.g., measurements) of an RF transmitter and/or multiple RF transmitters, for example, under various operating conditions as further discussed herein.

The model training host may use the labels 806 to evaluate the performance of the ML model 808 and adjust the ML model 808 (e.g., weights of the ANN 700) as described herein. Each of the labels 806 may be associated with at least one of the antenna impedances of the training input data 804. In certain cases, each of the labels 806 may include an expected tuning index for the respective antenna impedance. In some cases, each of the labels 806 may include a performance metric (e.g., EVM, output power, etc.) for the expected tuning index.

The model training host provides the training input data 804 to an ML model 808. In certain aspects, the ML model 808 may include a neural network. The ML model 808 may be an example of the ML model(s) described herein with respect to FIGS. 2, 3, 6, and 7. The ML model 808 provides output data 810, which may include an indication of a tuning index for the impedance tuning circuit 304.

The model training host may evaluate the performance of the ML model 808 and determine whether to update the ML model 808, for example, based on the performance achieved with the predicted tuning index. The model training host may evaluate the quality and/or accuracy of the output data 810. In some cases, the model training host may determine whether the output data 810 matches the corresponding label 806 of the training input data 804. For example, the model training host may determine whether the predicted tuning index output by the ML model 808 matches the expected tuning index of the corresponding label 806. In some cases, the performance evaluation may determine whether the predicted tuning index achieves the performance metric associated with the expected tuning index of the corresponding label 806.

In certain aspects, the model training host may evaluate the performance of the ML model 808 using a cost or loss function 812 (hereinafter “the loss function 812”). The loss function 812 may be or include a comparison between the expected tuning index corresponding to the label 806 and the predicted tuning index output by the ML model 808. In some cases, the loss function 812 may be or include a comparison between the expected performance corresponding to the tuning index of the label 806 and the actual performance of the RF transmitter configured with the predicted tuning index of the output data 810. In certain aspects, the loss function 812 may be or include a difference between the actual performance of the RF transmitter configured with the predicted tuning index and the expected performance corresponding to the label 806, for example, as a mean squared error between the respective performance metrics. The loss function 812 may provide a loss value or score 814 based on the comparison of the output data 810 and the label 806.

The model training host may provide the loss score 814 to an optimizer 816, which may determine one or more updated weights 818 for the ML model 808. The optimizer 816 may adjust the ML model 808 (e.g., any of the weights in a layer of a neural network) to reduce the loss score 814 associated with the ML model 808. In certain aspects, the optimizer 816 may perform backpropagation to determine the updated weights 818. The model training host may continue to provide the training input data 804 to the ML model 808 and adjust the ML model 808 using the weights 818 until the loss score 814 of the ML model 808 satisfies a threshold and/or reaches a minimum value. The model training host may perform online training of the ML model 808 or train the ML model 808 using one or more batches of training data 802. In certain aspects, the optimizer 816 may be or include a root mean square propagation (RMSprop) optimizer, a descent gradient optimizer (e.g., a stochastic descent gradient (SGD)), a momentum optimizer, an Adam optimizer, etc. to minimize the loss score 814 associated with the ML-based multi-stage impedance tuning.

In certain aspects, the model training host may train the ML model 808 to satisfy certain criteria associated with the multi-stage impedance tuning. As an example, the model training host may train the ML model 808 to identify a tuning index that achieves certain performance metrics, such as a minimum EVM, a minimum ACLR, a maximum PAE, a maximum output power, a minimum PAPR, etc.

In certain aspects, the model training host may train multiple ML models to perform multi-stage impedance tuning. The ML models may be trained or configured with different model performance characteristics, different operating environments (e.g., RF environments), and/or different input-output schemes (e.g., different input data and different output data). For example, the ML models may be trained to predict a tuning index with different levels of accuracy (e.g., accuracies of 70%, 80%, or 99%) of meeting a target performance metric and/or different latencies (e.g., the processing time to predict the tuning index). Thus, the UE may select the ML model that is capable of predicting a tuning index in accordance with certain performance characteristic(s), operating environments, and/or input-output schemes as described above.

Note that the training architecture 800 is an example of deep learning, and any suitable training architecture may be used in addition to or instead of the training architecture 800 to train the ML model 808.

### Example Operations for Multi-Stage Impedance Tuning

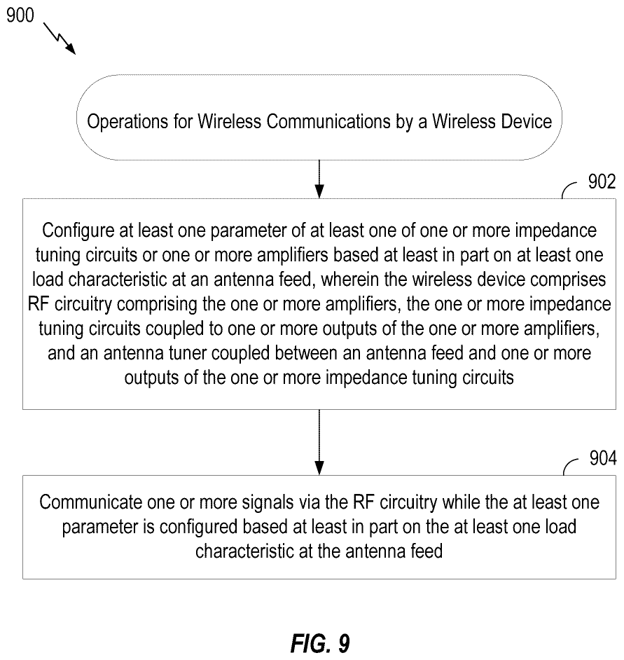

FIG. 9 illustrates example operations 900 for wireless communication. The operations 900 may be performed, for example, by a wireless device (e.g., the first wireless device 102 in the wireless communications system 100). In certain aspects, the operations 900 may be performed by an RF transmitter (e.g., the RF transmitter 300). The operations 900 may be implemented as software components that are executed and run on one or more processors (e.g., the modem 210 and/or the processor 212 of FIG. 2, and or the processor 362 of FIG. 3). Further, the transmission and/or reception of signals by the wireless device in the operations 900 may be enabled, for example, by one or more antennas (e.g., the antenna 220 of FIG. 2, and/or the antenna 310). In certain aspects, the transmission and/or reception of signals by the wireless device may be implemented via a bus interface of one or more processors (e.g., the modem 210 and/or the processor 212 of FIG. 2, and/or the processor 362 of FIG. 3) obtaining and/or outputting signals for reception or transmission.

The operations 900 may optionally begin, at block 902, where the wireless device configures at least one parameter of at least one of one or more impedance tuning circuits (e.g., the impedance tuning circuit 304) or one or more amplifiers (e.g., the amplifier 302) based at least in part on at least one load characteristic at an antenna feed (e.g., the antenna feed 332). In certain aspects, the wireless device comprises RF circuitry (e.g., the RF transmitter 300) comprising one or more amplifiers (e.g., the amplifier 302), the one or more impedance tuning circuits coupled to one or more outputs of the one or more amplifiers, and an antenna tuner (e.g., the antenna tuner 308) coupled between the antenna feed and one or more outputs of the one or more impedance tuning circuits. In certain aspects, the at least one load characteristic comprises one or more of a load impedance or a load phase at the antenna feed.

At block 904, the wireless device communicates one or more signals via the RF circuitry while the at least one parameter is configured based at least in part on the at least one load characteristic at the antenna feed. For example, the wireless device may transmit the signal(s) to another wireless communication device (e.g., any of the second wireless devices 104 depicted in FIG. 1). The signal may indicate (or carry) any of various information, such as data and/or control information. In some cases, the signal may indicate (or carry) one or more packets or data blocks.

In certain aspects, the wireless device may configure the at least one parameter to achieve (or predicted to achieve) one or more performance metrics at the at least one load characteristic. In certain aspects, the wireless device may configure the at least one parameter based at least in part on a relationship (e.g., the mapping 400) between one or more performance metrics associated with the RF circuitry and a combination of the at least one parameter and the at least one load characteristic.

In certain aspects, the at least one parameter comprises a tuning index of the one or more impedance tuning circuits. In certain aspects, the tuning index corresponds to a reactance value of at least one reactive component of the one or more impedance tuning circuits and/or a reference current (or biasing voltage or biasing current or quiescent current, which may be considered a reference current in some examples) applied to the one or more amplifiers. In certain aspects, the at least one parameter comprises one or more of: a reactance of at least one reactive component of the one or more impedance tuning circuits; or a reference current applied to the one or more amplifiers. In certain aspects, the one or more amplifiers comprise a driver amplifier and a power amplifier, and the reference current comprises a first reference current applied to the driver amplifier and a second reference current applied to the power amplifier.

In certain aspects, the one or more performance metrics comprise one or more of: an operating temperature of the RF circuitry; an output frequency of the RF circuitry; a voltage standing wave ratio (VSWR) of the RF circuitry; an error vector magnitude (EVM) of the RF circuitry; an adjacent channel leakage ratio (ACLR) of the RF circuitry; a peak-to-average power ratio (PAPR) of the RF circuitry; an output power level of the RF circuitry; or a power-added efficiency (PAE) of the one or more amplifiers. In certain aspects, the wireless device may monitor the one or more performance metrics and generate the relationship based on the monitored performance metric(s). In certain aspects, the wireless device may monitor the one or more performance metrics and configure the at least one parameter in response to a change in the monitored performance metric(s).

In certain aspects, the wireless device may set or configure an impedance of the antenna tuner based at least in part on the at least one load characteristic. The wireless device may set the impedance of the antenna tuner to match a load impedance and a load phase of the at least one load characteristic.

To configure the at least one parameter, the wireless device may use an ML model, for example, as described herein with respect to FIG. 3. The wireless device may provide, to an ML model, input data comprising the at least one load characteristic and/or one or more performance metrics associated with the RF circuitry. The wireless device may obtain, from the ML model, output data comprising the at least one parameter. The ML model may be trained to predict the at least one parameter that achieves one or more performance metrics associated with the RF circuitry. In certain aspects, the input data further comprises the at least one parameter and the at least one load characteristic in a first state (e.g., at a first time occasion), and the output data comprises the at least one parameter in a second state (e.g., a future or next time occasion) that is predicted to achieve one or more performance metrics associated with the RF circuitry at the at least one load characteristic. In certain aspects, the wireless device may train the ML model based at least in part on a heatmap that maps a plurality of values for the one or more performance metrics with combinations of the at least one load characteristic and the at least one parameter.

In certain aspects, to configure the at least one parameter, the wireless device may search for the at least one parameter in a heatmap that maps a plurality of values for one or more performance metrics associated with the RF circuitry with combinations of the at least one load characteristic and the at least one parameter. In certain aspects, the wireless device may search for the at least one parameter that achieves the one more performance metrics at the at least one load characteristic as represented by the heatmap.

### Example Communications Device

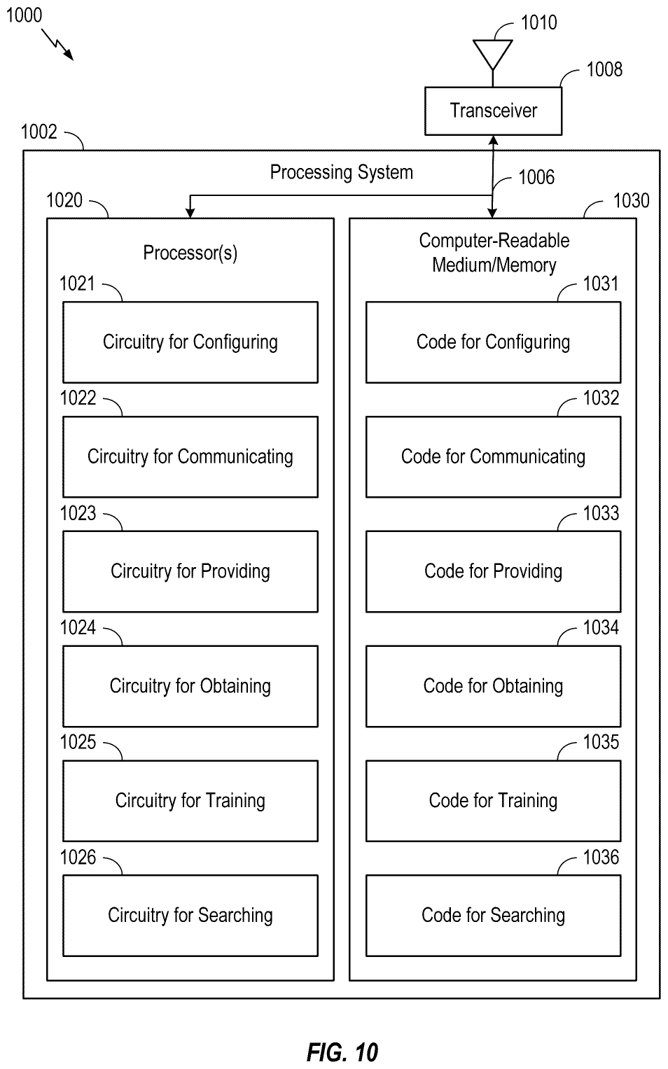

FIG. 10 depicts aspects of an example communications device 1000. In some aspects, communications device 1000 is a wireless communication device, such as the first wireless device 102 described above with respect to FIGS. 1 and 2. In certain aspects, the communications device 1000 may include an RF transmitter configured to perform the multi-stage impedance tuning described herein, such as the RF transmitter 300 of FIG. 3.

The communications device 1000 includes a processing system 1002 coupled to a transceiver 1008 (e.g., a transmitter and/or a receiver, and/or the RF transmitter 300 of FIG. 3). The transceiver 1008 is configured to transmit and receive signals for the communications device 1000 via an antenna 1010, such as the various signals described herein. The processing system 1002 may be configured to perform processing functions for the communications device 1000, including processing signals received and/or to be transmitted by the communications device 1000.

The processing system 1002 includes one or more processors 1020. In various aspects, the one or more processors 1020 may be representative of any of the modem 210 and/or the processor 212, as described with respect to FIG. 2. The one or more processors 1020 are coupled to a computer-readable medium/memory 1030 via a bus 1006. In certain aspects, the computer-readable medium/memory 1030 is configured to store instructions (e.g., computer-executable code) that when executed by the one or more processors 1020, cause the one or more processors 1020 to perform the operations 900 described with respect to FIG. 9, or any aspect related to the operations described herein. Note that reference to a processor performing a function of communications device 1000 may include one or more processors performing that function of communications device 1000. Reference to one or more processors performing multiple functions may include any one of the one or more processors performing any one of the multiple functions.

In the depicted example, computer-readable medium/memory 1030 stores code (e.g., processor-executable instructions) for configuring 1031, code for communicating 1032, code for providing 1033, code for obtaining 1034, code for training 1035, code for searching 1036, or any combination thereof. Processing of the code 1031-1036 may cause the communications device 1000 to perform the operations 900 described with respect to FIG. 9, or any aspect related to operations described herein.

The one or more processors 1020 include circuitry configured to implement (e.g., execute) the code stored in the computer-readable medium/memory 1030, including circuitry for configuring 1021, circuitry for communicating 1022, circuitry for providing 1023, circuitry for obtaining 1024, circuitry for training 1025, circuitry for searching 1026, or any combination thereof. Processing with circuitry 1021-1026 may cause the communications device 1000 to perform the operations 900 described with respect to FIG. 9, or any aspect related to operations described herein.

Various components of the communications device 1000 may provide means for performing the operations 900 described with respect to FIG. 9, or any aspect related to operations described herein. For example, means for communicating, transmitting, sending or outputting for transmission may include the TX path 218 and/or antenna(s) 220 of the first wireless device 102 illustrated in FIG. 2 and/or transceiver 1008 and antenna 1010 of the communications device 1000 in FIG. 10. Means for communicating, receiving, or obtaining may include the RX path 222 and/or antenna(s) 220 of the first wireless device illustrated in FIG. 2 and/or transceiver 1008 and antenna 1010 of the communications device 1000 in FIG. 10. Means for configuring, providing, obtaining, training, and/or searching may include one or more processors, such as the modem 210 and/or processor 212 depicted in FIG. 2 and/or the processor(s) 1020 in FIG. 10.

### Example Aspects

Implementation examples are described in the following numbered clauses:

Aspect 1: An apparatus s configured for wireless communications, comprising: radio frequency (RF) circuitry comprising: one or more amplifiers, one or more impedance tuning circuits coupled to one or more outputs of the one or more amplifiers, and an antenna tuner coupled between an antenna feed and one or more outputs of the one or more impedance tuning circuits; one or more memories; and one or more processors coupled to the one or more memories, the one or more processors being configured to cause the apparatus to: configure at least one parameter of at least one of the one or more impedance tuning circuits or the one or more amplifiers based at least in part on at least one load characteristic at the antenna feed; and communicate one or more signals via the RF circuitry while the at least one parameter is configured based at least in part on the at least one load characteristic at the antenna feed.

Aspect 2: The apparatus of Aspect 1, wherein to configure the at least one parameter, the one or more processors are configured to cause the apparatus to configure the at least one parameter to achieve one or more performance metrics at the at least one load characteristic.

Aspect 3: The apparatus of Aspect 1 or 2, wherein to configure the at least one parameter, the one or more processors are configured to cause the apparatus to configure the at least one parameter based at least in part on a relationship between one or more performance metrics associated with the RF circuitry and a combination of the at least one parameter and the at least one load characteristic.

Aspect 4: The apparatus of Aspect 2 or 3, wherein the one or more performance metrics comprise one or more of: an operating temperature of the RF circuitry; an output frequency of the RF circuitry; a voltage standing wave ratio (VSWR) of the RF circuitry; an error vector magnitude (EVM) of the RF circuitry; an adjacent channel leakage ratio (ACLR) of the RF circuitry; a peak-to-average power ratio (PAPR) of the RF circuitry; an output power level of the RF circuitry; or a power-added efficiency (PAE) of the one or more amplifiers.

Aspect 5: The apparatus according to any of Aspects 2-4, wherein: the at least one load characteristic comprises one or more of a load impedance or a load phase at the antenna feed; and the at least one parameter comprises a tuning index of the one or more impedance tuning circuits.

Aspect 6: The apparatus of Aspect 5, wherein the tuning index corresponds to a reactance value of at least one reactive component of the one or more impedance tuning circuits.

Aspect 7: The apparatus according to any of Aspects 1-6, wherein the at least one parameter comprises one or more of: a reactance of at least one reactive component of the one or more impedance tuning circuits; or a reference current applied to the one or more amplifiers.

Aspect 8: The apparatus of Aspect 7, wherein: the one or more amplifiers comprise a driver amplifier and a power amplifier; and the reference current comprises a first reference current applied to the driver amplifier and a second reference current applied to the power amplifier.

Aspect 9: The apparatus according to any of Aspects 1-8, wherein the one or more processors are configured to cause the apparatus to set an impedance of the antenna tuner based at least in part on the at least one load characteristic.

Aspect 10: The apparatus of Aspect 9, wherein to set the impedance of the antenna tuner, the one or more processors are configured to cause the apparatus to set the impedance of the antenna tuner to match a load impedance and a load phase of the at least one load characteristic.

Aspect 11: The apparatus according to any of Aspects 1-10, wherein to configure the at least one parameter, the one or more processors are configured to cause the apparatus to: provide, to a machine learning (ML) model, input data comprising the at least one load characteristic; and obtain, from the ML model, output data comprising the at least one parameter.

Aspect 12: The apparatus of Aspect 11, wherein the ML model is trained to predict the at least one parameter that achieves one or more performance metrics associated with the RF circuitry.

Aspect 13: The apparatus of Aspect 11 or 12, wherein: the input data further comprises the at least one parameter and the at least one load characteristic in a first state; and the output data comprises the at least one parameter in a second state that is predicted to achieve one or more performance metrics associated with the RF circuitry at the at least one load characteristic.

Aspect 14: The apparatus according to any of Aspects 11-13, wherein the one or more processors are configured to cause the apparatus to train the ML model based at least in part on a heatmap that maps a plurality of values for one or more performance metrics associated with the RF circuitry with combinations of the at least one load characteristic and the at least one parameter.

Aspect 15: The apparatus according to any of Aspects 1-14, wherein to configure the at least one parameter, the one or more processors are configured to cause the apparatus to search for the at least one parameter in a heatmap that maps a plurality of values for one or more performance metrics associated with the RF circuitry with combinations of the at least one load characteristic and the at least one parameter.

Aspect 16: The apparatus of Aspect 15, wherein to search for the at least one parameter, the one or more processors are configured to cause the apparatus to search for the at least one parameter that achieves the one more performance metrics at the at least one load characteristic as represented by the heatmap.

Aspect 17: A method of wireless communications by an apparatus, comprising: configuring at least one parameter of at least one of one or more impedance tuning circuits or one or more amplifiers based at least in part on at least one load characteristic at an antenna feed, wherein the apparatus comprises radio frequency (RF) circuitry comprising the one or more amplifiers, the one or more impedance tuning circuits coupled to one or more outputs of the one or more amplifiers, and an antenna tuner coupled between the antenna feed and one or more outputs of the one or more impedance tuning circuits; and communicating one or more signals via the RF circuitry while the at least one parameter is configured based at least in part on at least one load characteristic at the antenna feed.

Aspect 18: The method of Aspect 17, wherein configuring the at least one parameter comprises configuring the at least one parameter to achieve one or more performance metrics at the at least one load characteristic.

Aspect 19: The method of Aspect 17 or 18, wherein configuring the at least one parameter comprises configuring the at least one parameter based at least in part on a relationship between one or more performance metrics associated with the RF circuitry and a combination of the at least one parameter and the at least one load characteristic.

Aspect 20: The method of Aspect 18 or 19, wherein the one or more performance metrics comprise one or more of: an operating temperature of the RF circuitry; an output frequency of the RF circuitry; a voltage standing wave ratio (VSWR) of the RF circuitry; an error vector magnitude (EVM) of the RF circuitry; an adjacent channel leakage ratio (ACLR) of the RF circuitry; a peak-to-average power ratio (PAPR) of the RF circuitry; an output power level of the RF circuitry; or a power-added efficiency (PAE) of the one or more amplifiers.

Aspect 21: The method according to any of Aspects 18-20, wherein: the at least one load characteristic comprises one or more of a load impedance or a load phase at the antenna feed; and the at least one parameter comprises a tuning index of the one or more impedance tuning circuits.

Aspect 22: The method of Aspect 21, wherein the tuning index corresponds to a reactance value of at least one reactive component of the one or more impedance tuning circuits.

Aspect 23: The method according to any of Aspects 17-22, wherein the at least one parameter comprises one or more of: a reactance of at least one reactive component of the one or more impedance tuning circuits; or a reference current applied to the one or more amplifiers.

Aspect 24: The method of Aspect 23, wherein: the one or more amplifiers comprise a driver amplifier and a power amplifier; and the reference current comprises a first reference current applied to the driver amplifier and a second reference current applied to the power amplifier.

Aspect 25: The method according to any of Aspects 17-24, further comprising setting an impedance of the antenna tuner based at least in part on the at least one load characteristic.

Aspect 26: The method of Aspect 25, wherein setting the impedance of the antenna tuner comprises setting the impedance of the antenna tuner to match a load impedance and a load phase of the at least one load characteristic.

Aspect 27: The method according to any of Aspects 17-26, wherein configuring the at least one parameter comprises: providing, to a machine learning (ML) model, input data comprising the at least one load characteristic; and obtaining, from the ML model, output data comprising the at least one parameter.

Aspect 28: The method of Aspect 27, wherein the ML model is trained to predict the at least one parameter that achieves one or more performance metrics associated with the RF circuitry.

Aspect 29: The method of Aspect 27 or 28, wherein: the input data comprises the at least one parameter and the at least one load characteristic in a first state; and the output data comprises the at least one parameter in a second state that is predicted to achieve one or more performance metrics associated with the RF circuitry at the at least one load characteristic.

Aspect 30: The method according to any of Aspects 27-29, further comprising training the ML model based at least in part on a heatmap that maps a plurality of values for one or more performance metrics associated with the RF circuitry with combinations of the at least one load characteristic and the at least one parameter.

Aspect 31: The method according to any of Aspects 17-30, wherein configuring the at least one parameter comprises searching for the at least one parameter in a heatmap that maps a plurality of values for one or more performance metrics associated with the RF circuitry with combinations of the at least one load characteristic and the at least one parameter.

Aspect 32: The method of Aspect 31, wherein searching for the at least one parameter comprises searching for the at least one parameter that achieves the one more performance metrics at the at least one load characteristic as represented by the heatmap.

Aspect 33: A radio frequency transmitter, comprising: one or more amplifiers; one or more impedance tuning circuits coupled to one or more outputs of the one or more amplifiers; an antenna tuner coupled between an antenna feed and one or more outputs of the one or more impedance tuning circuits; one or more memories; and one or more processors coupled to the one or more memories, the one or more processors being configured to: configure a tuning index of at least one of the one or more impedance tuning circuits or the one or more amplifiers based at least in part on at least one load characteristic at the antenna feed; and communicate one or more signals while the tuning index is configured based at least in part on the at least one load characteristic at the antenna feed.

Aspect 34: An apparatus, comprising: a memory; and one or more processors configured to perform a method in accordance with any of Aspects 17-32.

Aspect 35: An apparatus, comprising means for performing a method in accordance with any of Aspects 17-32.

Aspect 36: A non-transitory computer-readable medium comprising computer-executable instructions that, when executed by one or more processors of a processing system, cause the processing system to perform a method in accordance with any of Aspects 17-32.

Aspect 37: A computer program product embodied on a computer-readable storage medium comprising code for performing a method in accordance with any of Aspects 17-32.

### Additional Considerations

The preceding description is provided to enable any person skilled in the art to practice the various aspects described herein. The examples discussed herein are not limiting of the scope, applicability, or aspects set forth in the claims. Various modifications to these aspects will be readily apparent to those skilled in the art, and the general principles defined herein may be applied to other aspects. For example, changes may be made in the function and arrangement of elements discussed without departing from the scope of the disclosure. Various examples may omit, substitute, or add various procedures or components as appropriate. For instance, the methods described may be performed in an order different from that described, and various actions may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

The various illustrative logical blocks, modules and circuits described in connection with the present disclosure may be implemented or performed with a microcontroller, a microprocessor, a general-purpose processor, a digital signal processor (DSP), an artificial intelligence processor, an application specific integrated circuit (ASIC), a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, a system on a chip (SoC), or any other such configuration.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining, and the like. Also, “determining” may include receiving (e.g., receiving information), accessing (e.g., accessing data in a memory), and the like. Also, “determining” may include resolving, selecting, identifying, mapping, applying, choosing, establishing, and the like.

The methods disclosed herein comprise one or more actions for achieving the methods. The method actions may be interchanged with one another without departing from the scope of the claims. In other words, unless a specific order of actions is specified, the order and/or use of specific actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor.

The following claims are not intended to be limited to the aspects shown herein, but are to be accorded the full scope consistent with the language of the claims. Within a claim, reference to an element in the singular is not intended to mean “one and only one” unless specifically so stated, but rather “one or more.” The use of a definite article (e.g., “the” or “said”) before an element is not intended to impart a singular meaning (e.g., “one and only one”) on an otherwise plural meaning (e.g., “one or more”) associated with the element unless specifically so stated. Unless specifically stated otherwise, the term “some” refers to one or more. No claim element is to be construed under the provisions of 35 U.S.C. § 112 (f) unless the element is expressly recited using the phrase “means for.” All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

1. An apparatus configured for wireless communications, comprising:
radio frequency (RF) circuitry comprising:
one or more amplifiers,
one or more impedance tuning circuits coupled to one or more outputs of the one or more amplifiers, and
an antenna tuner coupled between an antenna feed and one or more outputs of the one or more impedance tuning circuits;
one or more memories; and
one or more processors coupled to the one or more memories, the one or more processors being configured to cause the apparatus to:
configure at least one parameter of at least one of the one or more impedance tuning circuits or the one or more amplifiers based at least in part on at least one load characteristic at the antenna feed; and
communicate one or more signals via the RF circuitry while the at least one parameter is configured based at least in part on the at least one load characteristic at the antenna feed.

2. The apparatus of claim 1, wherein to configure the at least one parameter, the one or more processors are configured to cause the apparatus to configure the at least one parameter to achieve one or more performance metrics at the at least one load characteristic.

3. The apparatus of claim 1, wherein to configure the at least one parameter, the one or more processors are configured to cause the apparatus to configure the at least one parameter based at least in part on a relationship between one or more performance metrics associated with the RF circuitry and a combination of the at least one parameter and the at least one load characteristic.

4. The apparatus of claim 2, wherein the one or more performance metrics comprise one or more of:
a voltage standing wave ratio (VSWR) of the RF circuitry;
an error vector magnitude (EVM) of the RF circuitry;
an adjacent channel leakage ratio (ACLR) of the RF circuitry;
a peak-to-average power ratio (PAPR) of the RF circuitry;
an output power level of the RF circuitry; or
a power-added efficiency (PAE) of the one or more amplifiers.

5. The apparatus of claim 2, wherein:
the at least one load characteristic comprises one or more of a load impedance or a load phase at the antenna feed; and
the at least one parameter comprises a tuning index of the one or more impedance tuning circuits.

6. The apparatus of claim 5, wherein the tuning index corresponds to a reactance value of at least one reactive component of the one or more impedance tuning circuits.

7. The apparatus of claim 1, wherein the at least one parameter comprises one or more of:
a reactance of at least one reactive component of the one or more impedance tuning circuits; or
a reference current applied to the one or more amplifiers.

8. The apparatus of claim 7, wherein:
the one or more amplifiers comprise a driver amplifier and a power amplifier; and
the reference current comprises a first reference current applied to the driver amplifier and a second reference current applied to the power amplifier.

9. The apparatus of claim 1, wherein the one or more processors are configured to cause the apparatus to set an impedance of the antenna tuner based at least in part on the at least one load characteristic.

10. The apparatus of claim 9, wherein to set the impedance of the antenna tuner, the one or more processors are configured to cause the apparatus to set the impedance of the antenna tuner to match a load impedance and a load phase of the at least one load characteristic.

11. The apparatus of claim 1, wherein to configure the at least one parameter, the one or more processors are configured to cause the apparatus to:
provide, to a machine learning (ML) model, input data comprising the at least one load characteristic; and
obtain, from the ML model, output data comprising the at least one parameter.

12. The apparatus of claim 11, wherein the ML model is trained to predict the at least one parameter that achieves one or more performance metrics associated with the RF circuitry.

13. The apparatus of claim 11, wherein:
the input data further comprises the at least one parameter and the at least one load characteristic in a first state; and
the output data comprises the at least one parameter in a second state that is predicted to achieve one or more performance metrics associated with the RF circuitry at the at least one load characteristic.

14. The apparatus of claim 11, wherein the one or more processors are configured to cause the apparatus to train the ML model based at least in part on a heatmap that maps a plurality of values for one or more performance metrics associated with the RF circuitry with combinations of the at least one load characteristic and the at least one parameter.

15. The apparatus of claim 1, wherein to configure the at least one parameter, the one or more processors are configured to cause the apparatus to search for the at least one parameter in a heatmap that maps a plurality of values for one or more performance metrics associated with the RF circuitry with combinations of the at least one load characteristic and the at least one parameter.

16. The apparatus of claim 15, wherein to search for the at least one parameter, the one or more processors are configured to cause the apparatus to search for the at least one parameter that achieves the one more performance metrics at the at least one load characteristic as represented by the heatmap.

17. A method of wireless communications by an apparatus, comprising:
configuring at least one parameter of at least one of one or more impedance tuning circuits or one or more amplifiers based at least in part on at least one load characteristic at an antenna feed, wherein the apparatus comprises radio frequency (RF) circuitry comprising the one or more amplifiers, the one or more impedance tuning circuits coupled to one or more outputs of the one or more amplifiers, and an antenna tuner coupled between the antenna feed and one or more outputs of the one or more impedance tuning circuits; and
communicating one or more signals via the RF circuitry while the at least one parameter is configured based at least in part on at least one load characteristic at the antenna feed.

18. The method of claim 17, wherein configuring the at least one parameter comprises configuring the at least one parameter to achieve one or more performance metrics at the at least one load characteristic.

19. The method of claim 17, wherein:
configuring the at least one parameter comprises configuring the at least one parameter based at least in part on a relationship between one or more performance metrics associated with the RF circuitry and a combination of the at least one parameter and the at least one load characteristic;
the at least one load characteristic comprises one or more of a load impedance or a load phase at the antenna feed; and
the at least one parameter comprises a tuning index of the one or more impedance tuning circuits.

20. A radio frequency transmitter, comprising:
one or more amplifiers;
one or more impedance tuning circuits coupled to one or more outputs of the one or more amplifiers;
an antenna tuner coupled between an antenna feed and one or more outputs of the one or more impedance tuning circuits;
one or more memories; and
one or more processors coupled to the one or more memories, the one or more processors being configured to:
configure a tuning index of at least one of the one or more impedance tuning circuits or the one or more amplifiers based at least in part on at least one load characteristic at the antenna feed; and
communicate one or more signals while the tuning index is configured based at least in part on the at least one load characteristic at the antenna feed.
